(19) United States
(12) Patent Application Publication
(10) Pub. No.: US 2022/0271050 A1
(43) Pub. Date: Aug. 25, 2022

(54) SEMICONDUCTOR DEVICE AND METHOD FOR MANUFACTURING THE SAME

(71) Applicant: KIOXIA CORPORATION, Tokyo (JP)

(72) Inventors: Mitsuhiro NOGUCHI, Yokohama Kanagawa (JP); Masahiro SHIMURA, Yokohama Kanagawa (JP)

(21) Appl. No.: 17/459,054

(22) Filed: Aug. 27, 2021

(30) Foreign Application Priority Data
Feb. 22, 2021 (JP) 2021-026139

(51) Int. Cl. H01L 27/11529; H01L 27/11573; H01L 27/11556; H01L 27/11582

(52) U.S. Cl. CPC H01L 27/11529; H01L 27/11573; H01L 27/11556; H01L 27/11582

(57) ABSTRACT

A semiconductor device for controlling memory cell transistors includes a substrate, a first well of a first conductivity type in the substrate, a second well of a second conductivity type that electrically separates the first well from the substrate therein and includes a first portion surrounding the first well, and a second portion facing a bottom portion of the first well and having a side surface contacting a side surface of the first portion, a third well of the first conductivity type in the substrate, the third well surrounding the first portion of the second well with being separated therefrom, and a first transistor that includes a gate electrode facing the first well via a first insulating film. A bottom surface of the first portion of the second well is closer to a surface of the substrate than a bottom surface of the second portion of the second well.

### CROSS-REFERENCE TO RELATED APPLICATION

This application is based upon and claims the benefit of priority from Japanese Patent Application No. 2021-026139, filed Feb. 22, 2021, the entire contents of which are incorporated herein by reference.

### FIELD

Embodiments described herein relate generally to a semiconductor device having a double-well structure and a method for manufacturing the same.

### BACKGROUND

A semiconductor device including a semiconductor element can be formed on a semiconductor substrate using a double-well structure in which a well of a conductivity type different from the semiconductor substrate is formed along with another well having the same conductivity type as the semiconductor substrate. With such a double-well structure, a required chip area increases because the different wells need to be formed in the semiconductor substrate adjacent to one another and the associated manufacturing costs also increase since the wells need to be formed at deep positions in the semiconductor substrate.

### BRIEF DESCRIPTION OF THE DRAWINGS

FIG. 1 is a schematic cross-sectional view of a semiconductor device according to a first embodiment.

FIG. 2 is a schematic circuit diagram of a semiconductor memory.

FIG. 3 is a schematic cross-sectional view of a memory cell.

FIG. 4 is a schematic perspective view of memory strings.

FIG. 5 is a schematic perspective view of a memory cell array.

FIG. 6 is a graph illustrating an impurity concentration profile of a semiconductor device according to a first embodiment.

FIG. 7 is a schematic cross-sectional view of a semiconductor device of a comparative example.

FIG. 8 is a graph illustrating an impurity concentration profile of a semiconductor device of a comparative example.

FIGS. 9A to 9H illustrate aspects related to a method of manufacturing a semiconductor device of the comparative example.

FIGS. 10A to 10D illustrate aspects related to a method of manufacturing a semiconductor device according to a first embodiment.

FIG. 11 is a schematic cross-sectional view of a semiconductor device according to a modified example of a first embodiment.

FIG. 12A is a schematic cross-sectional view illustrating a method of manufacturing a semiconductor device of a modified example of a first embodiment.

FIG. 12B is a schematic plan view illustrating a method of manufacturing a semiconductor device of a modified example of a first embodiment.

FIG. 13 is a schematic cross-sectional view of a semiconductor device according to a second embodiment.

FIG. 14 is a graph illustrating an impurity concentration profile of a semiconductor device according to a second embodiment.

FIG. 15A is a schematic cross-sectional view illustrating a method of manufacturing a semiconductor device according to a second embodiment.

FIG. 15B is a schematic plan view illustrating a method of manufacturing a semiconductor device according to a second embodiment.

FIG. 15C is a schematic plan view illustrating an example of an exposure mask used for manufacturing a semiconductor device according to a second embodiment.

FIG. 16 is a schematic cross-sectional view of a semiconductor device according to a modified example of a second embodiment.

FIG. 17A is a schematic cross-sectional view illustrating a method of manufacturing a semiconductor device according to a modified example of a second embodiment.

FIG. 17B is a schematic plan view illustrating a method of manufacturing a semiconductor device according to a modified example of a second embodiment.

### DETAILED DESCRIPTION

Embodiments provide a semiconductor device having a double-well structure that is capable of preventing an increase in chip area and an increase in manufacturing cost and a method for manufacturing the semiconductor device.

In general, according to one embodiment, a semiconductor device for controlling a plurality of memory cell transistors includes a semiconductor substrate, a first well of a first conductivity type in the substrate, a second well of a second conductivity type that electrically separates the first well from the substrate therein and includes a first portion surrounding the first well, and a second portion facing a bottom portion of the first well and having a side surface contacting a side surface of the first portion, a third well of the first conductivity type in the substrate, the third well surrounding the first portion of the second well with being separated therefrom, and a first transistor that includes a gate electrode facing the first well via a first insulating film. A bottom surface of the first portion of the second well is closer to a surface of the substrate than a bottom surface of the second portion of the second well.

Next, certain example embodiments will be described with reference to the drawings. In the description of the drawings, the same components are denoted by the same reference numerals. The drawings are schematic. In addition, the embodiments illustrated in the drawings are presented for purposes of explaining certain devices and methods embodying technical concepts of the present disclosure and do not limit the possible materials, shapes, structures, arrangements, and the like of the various parts that may be utilized while still embodying the described technical concepts. The described embodiments may be modified in various aspects.

### First Embodiment

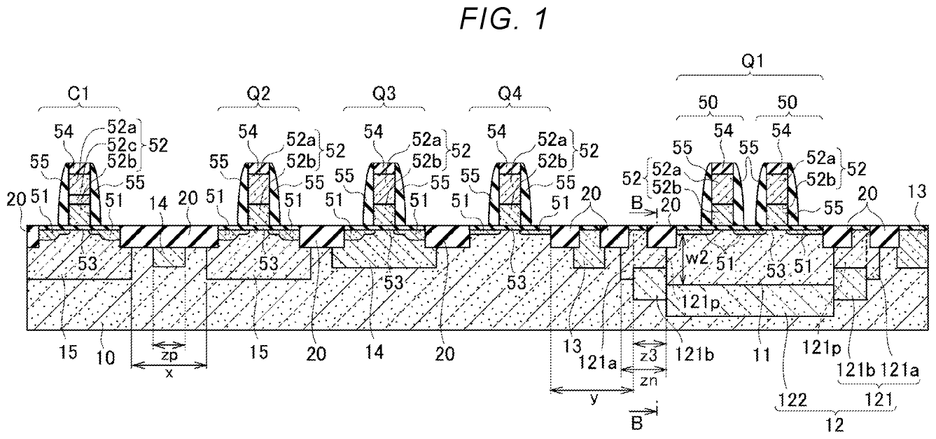

FIG. 1 illustrates a configuration of a semiconductor device Q1 according to a first embodiment. The semiconductor device Q1 is used for a peripheral circuit of a semiconductor memory. The peripheral circuit controls operations of a memory cell array including a plurality of memory cell transistors (hereinafter, also referred to as “memory cells”).

The semiconductor device Q1 includes a first well 11 of a first conductivity type formed in a semiconductor substrate 10, which is also of the first conductivity type, and a second well 12 of a second conductivity type. The second well 12 is formed in a region between the semiconductor substrate 10 and the first well 11 and functions to electrically separate the semiconductor substrate 10 from the first well 11. The second well 12 has a first portion 121 that surrounds the side surface of the first well 11 and a second portion 122 that is connected to the first portion 121 and covers a bottom portion of the first well 11. The first portion 121 is connected to the side surface of the second portion 122. In addition, a third well 13 of the first conductivity type is formed in an upper portion of the semiconductor substrate 10 so as to be separated from the second well 12. The third well 13 surrounds the side surface of the first well 11 and the second well 12.

In the present example, the first conductivity type is P type, and the second conductivity type is N type. Therefore, the first well 11 and the third well 13 are P-type wells, and the second well 12 is an N-type well. The P-type semiconductor substrate 10 is, for example, a silicon (Si) substrate. The impurity concentration of the semiconductor substrate 10 is lower than 10¹⁵ cm⁻³.

The first portion 121 of the second well 12 includes a side surface region 121a that covers an upper portion of the side surface of the first well 11 and a connection region 121b that covers a lower portion of the side surface of the first well 11 and connects the side surface region 121a and the second portion 122. An upper surface of the side surface region 121a is exposed at the upper surface of the semiconductor substrate 10, and the connection region 121b is formed below the side surface region 121a. The side surface of the upper portion of the connection region 121b is connected to the first well 11, and the side surface of the lower portion of the connection region 121b is connected to the outer edge of the second portion 122.

As viewed from a direction normal to the main surface of the semiconductor substrate 10 (hereinafter, such a view is referred to as “a plan view”), the boundary between the side surface region 121a and the first well 11 and the boundary between the connection region 121b and the second portion 122 match with each other. In addition, the bottom surface of the first portion 121 of the second well 12 is at a position shallower within the semiconductor substrate 10 than is the position of the bottom surface of the second portion 122 of the second well 12.

The second well 12 has a recess or bowl shape in which the first portion 121 forms a side portion and the second portion 122 forms a bottom portion. In the semiconductor substrate 10, the periphery of the first well 11 is surrounded by the first portion 121 and the second portion 122 of the second well 12. The semiconductor device Q1 has a double-well structure, and the first well 11 is electrically separated from the semiconductor substrate 10 by the second well 12. Since the first well 11 is electrically separated from the semiconductor substrate 10, the voltage applied to the first well 11 can be controlled independently of the potential of the semiconductor substrate 10.

In the semiconductor device Q1 having the double-well structure, the region of the first well 11 can be made smaller in size and depth than that of the full semiconductor substrate 10. For this reason, for example, when a voltage is applied to the first well 11, as compared with the case where the voltage is applied to the semiconductor substrate 10, the load of a booster circuit can be reduced, and the power consumption can be reduced.

For forming the double well, the second portion 122 of the second well 12 needs to be formed in a region in the semiconductor substrate 10, which is deeper into the semiconductor substrate 10 than the first well 11. In addition, for example, since the second portion 122 is formed in the P-type semiconductor substrate 10 that has an impurity concentration lower than 10¹⁵ cm⁻³, the impurity concentration of the second portion 122 is higher than 10¹⁵ cm⁻³. In order to maintain the potential of the second well 12 to be constant as a whole and in order to prevent leakage of crystal defects remaining due to ion implantation or otherwise the second portion 122 is formed so that the peak concentration of the N-type impurity concentration will be higher than 10¹⁶ cm⁻³ but lower than 10¹⁸ cm⁻³. Hereinafter, the peak concentration of an impurity is also simply referred to as a “peak concentration”.

As illustrated in FIG. 1, when the film thickness of the first well 11 is w2, the distance between the upper surface of the second portion 122 and the upper surface of the first well is greater than w2. For this reason, the second well 12 is expanded in the semiconductor substrate 10 such that the PN junction boundary with the first well 11 is located at a depth of 2 μm or more, typically 2 μm to 4 μm. In the semiconductor device Q1, the N-type peak concentration of the second well 12 is higher than the P-type peak concentration of the first well 11. It is noted that the “depth” in this context is taken as a distance from the upper surface of the semiconductor substrate 10 into the semiconductor substrate 10 in the substrate thickness direction.

The semiconductor device Q1 includes a plurality of field effect transistors (FET) 50 formed in the first well 11. Each FET 50 is an insulated gate type field effect transistor in which a pair of electrode diffusion layers 51 of the second conductivity type formed in the first well 11 are used as a first main electrode and a second main electrode. The FET 50 has a gate electrode 52 facing the first well 11 via a gate insulating film 53 formed on the upper surface of the first well 11. In a plan view, one electrode diffusion layer 51 is a source electrode and the other electrode diffusion layer 51 is a drain electrode with the gate electrode 52 interposed therebetween. A channel of the FET 50 is formed in the upper portion of the first well 11 located below the gate insulating film 53.

The gate insulating film 53 is, for example, a silicon oxide film or an oxynitride film having a film thickness of 20 nm to 40 nm. The gate electrode 52 is a conductive polysilicon film to which phosphorus or arsenic is added at a concentration in a range of, for example, 10¹⁸ cm⁻³ to 10²¹ cm⁻³. The thickness of the gate electrode 52 is, for example, 10 nm to 500 nm. The gate insulating film 53 of the FET 50 is also referred to as a “first gate insulating film”.

When a plurality of transistors are formed on the semiconductor substrate 10, the transistors are separated from each other by element separators 20 and the third well 13 formed on the surface of the semiconductor substrate 10. Each element separator 20 is formed by, for example, shallow trench isolation (STI) features by which an insulator is buried in a trench having a depth of 0.1 μm to 0.5 μm. The insulator to be buried in the trench is, for example, a silicon oxide film.

A plurality of FETs 50 separated from each other by the element separators 20 formed at a depth of 0.1 μm or more are formed in the first well 11. Each FET 50 is, for example, a switch transistor (hereinafter, also referred to as a “word line switch transistor”) that controls the voltage applied to the word line connected to the gate electrode of a memory cell of the semiconductor memory.

For example, films used as materials for the gate insulating film 53 and the gate electrode 52 are sequentially deposited on the entire surface of the first well 11, and these films are patterned to form the gate insulating film 53 and the gate electrode 52. Each element separator 20 forms the trench by etching a portion of the surface of the first well 11 to a depth of, for example, 0.1 μm to 0.5 μm and burying the portion with an insulator such as a silicon oxide film. In this manner, the gate electrode 52 can be formed on a flat surface.

An upper surface insulating film 54 is disposed on the upper surface of the gate electrode 52. The upper surface insulating film 54 is, for example, a silicon oxide film or a silicon nitride film. A side surface insulating film 55 is formed on a side surface of a gate structure including the gate electrode 52 and the upper surface insulating film 54. The material of the side surface insulating film 55 is, for example, a silicon nitride film or a silicon oxide film having a film thickness of 5 nm to 490 nm.

An N-type electrode diffusion layer 51 serving as a source electrode or a drain electrode of an FET 50 is formed in the first well 11. Hereinafter, a source electrode and/or a drain electrode can also be referred to as a “main electrode”. The electrode diffusion layer 51 contains, for example, phosphorus, arsenic, or antimony so that a surface concentration is 10¹⁷ cm⁻³ to 10²¹ cm⁻³. An example of the depth of the electrode diffusion layer 51 is 10 nm to 500 nm. The electrode diffusion layer 51 is formed in a self-aligned manner with respect to the gate structure. For example, when the FET 50 is a word line switch transistor, the main electrode of the FET 50 is connected to the gate electrode of a memory cell. In the following, either or both of the source electrode and the drain electrode of a FET 50 can also be referred to as a main electrode 51.

The material of the gate electrode 52 may be, for example, a conductive polysilicon film to which phosphorus, arsenic, or boron is added at a concentration of 10¹⁷ cm⁻³ to 10²¹ cm⁻³. In addition, the material of the gate electrode 52 may be a stacked structural film of tungsten silicide (WSi) and polysilicon, a stacked film of tungsten (W) and titanium nitride (TiN), or a stacked film of tungsten (W) and tungsten nitride (WN). In addition, the material of the gate electrode 52 may be a stacked structural film of nickel silicate (NiSi), molybdenum silicate (MoSi), titanium silicate (TiSi), cobalt silicate (CoSi), and polysilicon. An example of the thickness of the gate electrode 52 is 10 nm to 500 nm.

The gate length of an FET 50 is, for example, 2 μm to 0.8 μm. In addition, the electrode diffusion layer 51 may be shared by adjacent FETs 50, may be connected to a common wiring that applies a write voltage, and may be electrically connected to the word line connected to a memory cell. In this manner, the FETs 50 can be arranged in an array shape so that the area of the electrode diffusion layer 51 can be reduced and, thus, the semiconductor device Q1 can be highly integrated.

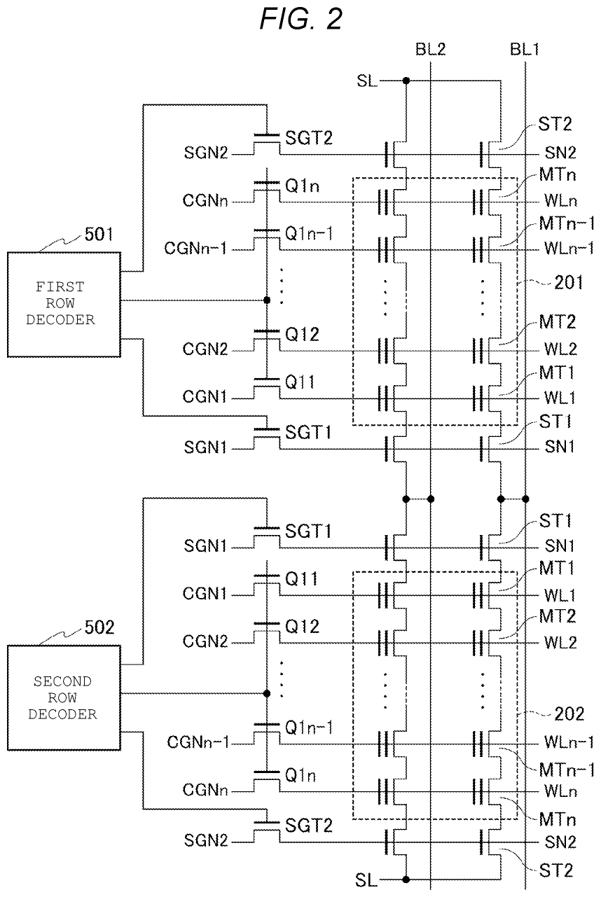

An example of using the semiconductor device Q1 as a peripheral circuit of a semiconductor memory will be described below. First, an example of the circuit configuration will be described with reference to FIG. 2.

FIG. 2 illustrates a circuit of a nonvolatile semiconductor memory including a first memory cell array 201, a second memory cell array 202, a first row decoder 501, and a second row decoder 502. The first row decoder 501 controls operations on the first memory cell array 201, and the second row decoder 502 controls operations on the second memory cell array 202. Hereinafter, the first row decoder 501 and the second row decoder 502 are also referred to as “row decoders 500”. The first memory cell array 201 and the second memory cell array 202 are also referred to as “memory cell arrays 200”. FIG. 2 illustrates the memory cell arrays 200 including two blocks (hereinafter, also referred to as “memory cell blocks”) in which a plurality of memory cells of a NAND type are connected in series.

One terminal of the memory cell block is connected to any one of data transfer lines BL1 and BL2 via a drain side select transistor ST1. Hereinafter, any one or all of the data transfer lines BL1 and BL2 are collectively referred to as “bit line(s) BL”. In addition, the other terminal of the memory cell block is connected to a source line SL via a source side select transistor ST2. The drain side select transistor ST1, the plurality of memory cells MT of the memory block, and the source side select transistor ST2 that are connected in series make up a “memory string” below.

A first select transistor SGT1 is connected to the gate electrode of each drain side select transistor ST1 via a drain side select gate line SN1. A second select transistor SGT2 is connected to the gate electrode of each source side select transistor ST2 via a source side select gate line SN2. Selection signals SGN1 and SGN2 for selecting one memory cell block from a plurality of the memory cell blocks are input to the drain side select gate line SN1 and the source side select gate line SN2 via the first select transistor SGT1 and the second select transistor SGT2. The first select transistor SGT1 and the second select transistor SGT2 are controlled by the row decoder 500.

One of data selection lines WL1, WL2, . . . WLn (where n is an integer of 16 or more) is connected to the gate electrodes of memory cells MT. In the following, any one or all of the data selection lines WL1, WL2, . . . WLn can be referred to as “a word line WL” and collectively each of the data selection lines WL1 . . . WLn may be referred to as “word lines WL”. The word line switch transistors Q11, Q12, . . . Q1n are connected to ends of the respective word lines WL. In the following, the word line switch transistors Q11, Q12, . . . Q1n are also referred to as “word line switch transistors QT”. Data control signals CGN1, CGN2, . . . CGNn are input to the gate electrodes of the memory cells MT via the word line switch transistors QT. The data control signals CGN1, CGN2, . . . CGNn are also referred to as “data control signals CGN”. The word line switch transistors QT are controlled by the row decoder 500.

The bit lines BL and the word lines WL are arranged in the direction to be orthogonal to each other. A memory cell MT is disposed at the intersection of each of the bit line BL and the word line WL and is associated with the bit line BL and the word line WL. Accordingly, each of the memory cells MT can independently store data.

The memory cell array 200 has a configuration in which a plurality of the memory cell blocks are arranged in the data transfer line direction and the data selection line direction. FIG. 2 illustrates a configuration in which the semiconductor memory has two memory cell arrays 200 and each memory cell array 200 has two memory cell blocks. The number of the memory cell arrays 200 and the number of the memory cell blocks of the semiconductor memory may be freely selected.

In FIG. 2, the word line switch structures of the two memory cell blocks are illustrated separately. It is noted that, with respect to the word line switch transistors QT, a source electrode or a drain electrode may be shared by the adjacent word line switch transistors. By sharing the source electrode or the drain electrode, the element area of the semiconductor memory can be reduced.

The row decoder 500 functions as a data selection line driver and is commonly connected to the gate electrodes of the word line switch transistors QT. The row decoder 500 controls the on/off state of each word line switch transistor QT by applying a voltage to the gate electrode of the word line switch transistor QT.

In the semiconductor memory illustrated in FIG. 2, a peripheral circuit including the row decoder 500, the first select transistor SGT1, the second select transistor SGT2, and the word line switch transistors QT controls operations of the memory cell array 200.

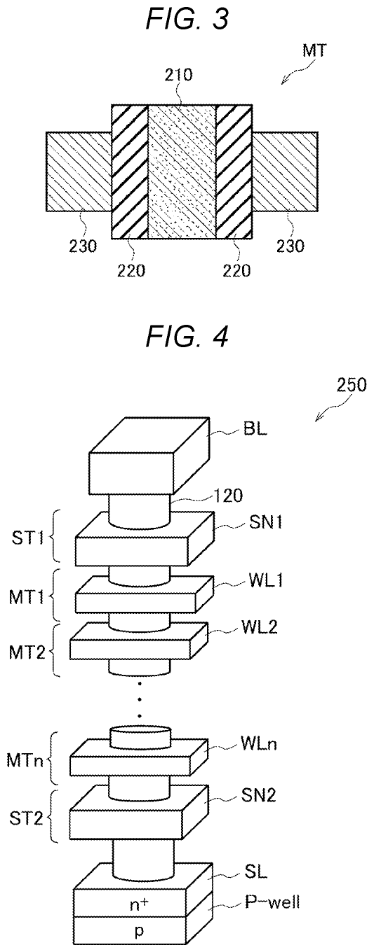

Each memory cell MT is a nonvolatile semiconductor storage element, for example, a charge trap type storage element as illustrated in FIG. 3. The memory cell MT illustrated in FIG. 3 includes a columnar semiconductor 210 having a channel region, a gate insulating film 220 disposed around the side surface of the columnar semiconductor 210 and including a charge storage layer, and an electrode layer 230 disposed around the gate insulating film 220. FIG. 3 is a cross-sectional view parallel to the central axis of the columnar semiconductor 210. The gate insulating film 220 is, for example, a stacked film (oxide/nitride/oxide film: ONO film) in which a silicon oxide film, a silicon nitride film, and a silicon oxide film are stacked in this order. When an ONO film is used for the gate insulating film 220, the SiN traps discretely distributed on the silicon nitride film store electric charges. One of the charge trap type storage elements is one of the memory cells MT of the memory cell array 200. The charge trap type storage element is a nonvolatile semiconductor storage element of which threshold voltage changes depending on the electric charges stored between the electrode layer 230 and the channel region. It is noted that, although the columnar semiconductor 210 is illustrated to have a columnar shape, the columnar semiconductor 210 may be a ring-shaped columnar semiconductor 210 in which the center of the column is hollowed out in a circular shape with, for example, a silicon oxide film in order to improve the current driving characteristics of the transistor.

FIG. 4 illustrates an example of memory strings 250 including the memory cells MT illustrated in FIG. 3. In the memory strings 250 illustrated in FIG. 4, the columnar semiconductor 210 is commonly used in the drain side select transistors ST1, the memory cells MT1 to MTn, and the source side select transistors ST2. That is, a plurality of electrode layers 230 are separated from each other along the central axis direction of the columnar semiconductor 210, and each of the electrode layers 230 is any one of a word line WL, a drain side select gate line SN1, and a source side select gate line SN2. Therefore, the region of the electrode layer 230 corresponding to the word line WL adjacent to the gate insulating film 220 is the gate electrode of each of the memory cells MT1 to MTn. That is, the electrode layer 230 corresponds to the gate electrode of each memory cell MT. It is noted that the gate insulating films that do not include the charge storage layers may be formed between the drain side select gate line SN1 and the columnar semiconductor 210 and between the source side select gate line SN2 and the columnar semiconductor 210 to reduce a fluctuation of the threshold value. In addition, by forming the gate insulating films that include the charge storage layers having the same configuration as the memory cell between the drain side select gate line SN1 and the columnar semiconductor 210 and between the source side select gate line SN2 and the columnar semiconductor 210 and controlling so that the voltage differences of the drain side select gate line SN1 and the source side select gate line SN2 with respect to the columnar semiconductor 210 are small, the fluctuation of the threshold due to the storing and discharging of the electric charges in the charge storage layer may be prevented.

The lower end of the columnar semiconductor 210 of the memory strings 250 is connected to the source line SL disposed on the P-type well of the substrate 10. The upper end of the columnar semiconductor 210 is connected to a bit line BL.

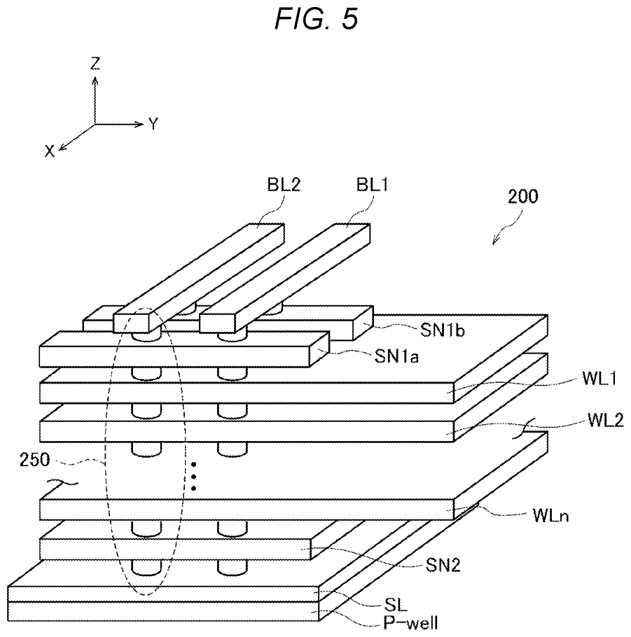

FIG. 5 illustrates an example of the memory cells MT arranged three-dimensionally. The memory cell array 200 illustrated in FIG. 5 has a configuration in which the memory strings 250 illustrated in FIG. 4 are arranged in a matrix in a plan view. The Z-axis direction in FIG. 5 is the direction along which each memory string 250 extends, and the X-axis direction is the direction along which each bit line BL extends. The word lines WL are arranged in a plate shape in parallel with the XY plane perpendicular to the Z-axis direction.

In the memory cell array 200 illustrated in FIG. 5, the word lines WL1 to WLn, the source side select gate line SN2, and the source line SL are connected to the memory strings 250 making up the memory cell array 200 and have a plate-shaped planar structure. That is, one of the word lines WL as a conductive layer is connected to the gate electrode of a memory cell MT of each memory string 250.

On the other hand, the drain side select gate lines SN1 are independent between the first memory cell array 201 and the second memory cell array 202. That is, a first drain side select gate line SN1a is connected to the gate electrode of the drain side select transistor ST1 of the first memory cell array 201. A first drain side select gate line SN1b is connected to the gate electrode of the drain side select transistor ST1 of the second memory cell array 202. The bit lines BL are connected to the first memory cell array 201 and the second memory cell array 202.

In the semiconductor memory having the memory cell array 200 in which memory cells MT are three-dimensionally arranged, for example, the peripheral circuit is formed around the memory cell array 200. A voltage higher than that of the memory cell MT is applied to each word line switch transistor QT in the peripheral circuit. For this reason, the semiconductor device Q1 having the double-well structure illustrated in FIG. 1 can be suitably applied to the word line switch transistors QT.

When the semiconductor device Q1 is applied to the word line switch transistors QT, all of the word line switch transistors QT connected to the row decoder 500 may be formed in the first well 11 having the same double-well structure. It is noted that, since the gate electrodes of the word line switch transistors QT are commonly connected and since the signal line through which the data control signal CGN propagates is shared in the adjacent memory cell blocks, the occupied area of the word line switch transistor QT can be reduced.

The operations of the semiconductor memory when the semiconductor device Q1 is applied to the word line switch transistors QT will be described below.

Data reading and data writing in the semiconductor memory maintains the voltage of the first well 11 on which the word line switch transistor QT is formed to be negative and decreases the voltage applied to the electrode diffusion layer 51. In this manner, by using the semiconductor device Q1 for each word line switch transistor QT, a negative voltage can be transferred to the word line WL, and thus, the same voltage is applied to the plurality of memory cell blocks. For this reason, as compared with the case where a channel voltage connected to the source line having a large capacitance changes, when the semiconductor device Q1 is applied to the word line switch transistors QT, the voltage divided for each word line WL can be applied. As a result, the operating speed of the semiconductor memory can be increased.

A voltage of 0 V or more in a range of, for example, 0 V to 4 V with respect to the semiconductor substrate 10 is applied to the second well 12. On the other hand, the voltage applied to the first well 11 is equal to or less than the voltage applied to the second well 12. A voltage in a range of, for example, −1 V to −4 V with reference to the semiconductor substrate 10 is applied to the first well 11. By disposing the second well 12 between the first well 11 and the semiconductor substrate 10 in this manner, a voltage lower than that of the semiconductor substrate 10 can be applied to the first well 11. Accordingly, even when the voltage applied to the main electrode formed in the first well 11 becomes negative with respect to the semiconductor substrate 10, the voltage applied to the first well 11 can be higher than the voltage applied to the main electrode. As a result, the semiconductor device Q1 can apply a negative voltage to the semiconductor substrate 10 while preventing junction leakage.

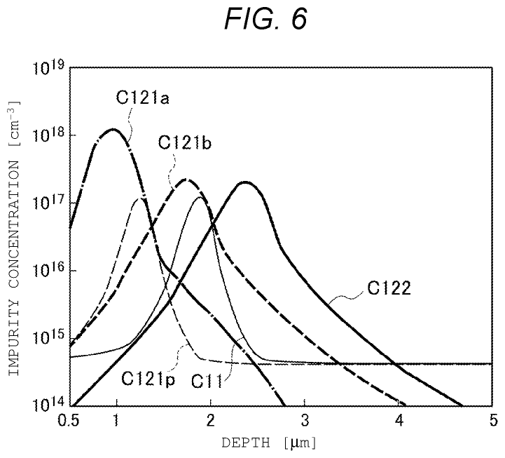

Hereinafter, the impurity concentration of the semiconductor device Q1 will be described with reference to FIG. 6. FIG. 6 illustrates an example of a profile (hereinafter, also referred to as an “impurity concentration profile”) of the impurity concentration of the semiconductor device Q1 in the depth direction in a cross section taken along the B-B direction of FIG. 1. In FIG. 6, C11 is the impurity concentration of the first well 11. C121a is the impurity concentration in the side surface region 121a of the second well 12, C121b is the impurity concentration in the connection region 121b of the second well 12, and C122 is the impurity concentration in the second portion 122 of the second well 12. In addition, in the manufacturing process of the semiconductor device Q1 described later, C121p is the P-type impurity concentration in the region (hereinafter, also referred to as “overlapping region 121p”) in which the P-type impurities of the side surface region 121a are implanted. The width of the overlapping region 121p is the same as a width z3 of the connection region 121b. The “width” in this context is the width as taken or apparent in a plan view.

With respect to the impurity concentration in the semiconductor substrate 10, the impurity concentration in the portion deeper than the bottom portion of the element separator 20 will be described. That is, the description of the impurity concentration profile by the ion implantation or the like in the portion less than the depth (for example, 0.5 μm) of the bottom portion of the element separator 20 will be omitted. Additionally, the description of the impurity concentration profile caused by ion implantation for adjusting the threshold value of the channel and the ion implantation for forming the source electrode and drain electrode of the transistor will be omitted.

The word line switch transistors QT described with reference to FIG. 2 are transistors for selecting one memory cell block from the plurality of memory cell blocks. When the semiconductor device Q1 is applied to the word line switch transistors QT, in order to uniformly control the threshold value by the plurality of word line switch transistors QT, the potential of the region in the first well 11 where the channel of an FET 50 is formed needs to be uniform. For this reason, a portion having a low resistance in the first well 11 is required. Furthermore, since the word line switch transistors QT need to apply a voltage of, for example, 15 V or more to the word lines, it is necessary to prevent the substrate bias effect of an NMOS of the semiconductor device Q1. In order to satisfy these two requirements, the first well 11 is formed so that the P-type impurity concentration is made lower than 10¹⁶ cm⁻³ within 1 μm from the surface and to have a peak higher than 10¹⁶ cm⁻³ in a depth range of 1.5 μm to 2.5 μm. As illustrated in FIG. 6, in a depth range of 1.5 μm to 2.5 μm, the peak concentration of the impurity concentration C11 of the first well 11 exceeds the impurity concentration obtained by combining the impurity concentration C121a of the side surface region 121a of the second well 12 and the impurity concentration C122 of the second portion 122.

In a NAND-type electrically erasable programmable read-only memory (EEPROM), a voltage of 15 V or more is applied to the channel and the gate electrodes as follows. In the operations of the NAND-type EEPROM, a tunnel current is used for implanting or discharging electric charges into the charge storage layer of the memory cell. The tunnel current flows through a tunnel insulating film disposed between the charge storage layer and the channel of the substrate. Even in the NOR-type flash memory, the tunnel current may be used in order to make it less susceptible to a short channel effect during erasing of data. For example, in order to increase the number of memory cells to be erased within a unit time, data stored in a plurality of memory cells is erased at the same time. For this reason, by applying a positive voltage of 15 V or more with reference to the gate electrode to the channel of the memory cell, electrons are extracted from the charge storage layer, or holes are implanted into the charge storage layer to be recombined with electrons. On the other hand, during writing of data, the voltage applied to the channel is maintained to be 0 V, and a voltage of 15 V or more is applied to the word line connected to the gate electrode of the selected memory cell. Accordingly, by implanting electrons from the channel into the charge storage layer, the writing to the memory cell is performed.

In the NAND-type EEPROM, when the distance between the source electrode and the drain electrode is shortened and the miniaturization is promoted, the threshold value of the MOS transistor of the EEPROM becomes low, and the threshold value is distributed on the more negative side. For this reason, in order to sufficiently widen the difference between the write threshold value and the erase threshold value as a memory cell, it is necessary to control the erase threshold value to be lower. For this reason, a negative voltage in a range of, for example, 0 V to −3 V is applied to the gate electrode of the selected memory cell as compared with the source electrode and the drain electrode. Then, an operation of determining read is performed by measuring a current value or a drain conductance between the source and the drain, in which the threshold value is negative.

A metal-lined wire whose capacitance is smaller than the capacitance of the source line shared by memory cell transistors of larger blocks and which has a low resistance may be used as the word line. In addition, in order to reduce the power consumption during the reading and to operate at a high speed, a negative voltage in a range of, for example, 0 V to −3 V is applied as the gate voltage of each memory cell. When the threshold value is set to positive by implanting electrons into the charge storage layer, the read operation is performed by applying a positive voltage in a range of, for example, 0 V to 7 V from the drain electrode as the gate voltage of the memory cell. For this reason, it is desirable to apply a voltage of a positive or negative polarity to the drain electrode.

As described above, by applying a positive or negative voltage with reference to the drain electrode of each memory cell to each word line connected to the gate electrode of the memory cell, as compared with the case where only a positive voltage is applied, it is possible to perform the read operation at a high speed with respect to the threshold value in a wide range. By applying the semiconductor device Q1 to the word line switch transistors QT, it is easy to apply a positive or negative voltage to each word line with respect to the drain electrode of each memory cell.

In order to reduce the power consumption of the peripheral circuit, the peripheral circuit of the semiconductor memory is implemented by, for example, a CMOS circuit. The CMOS circuit requires a P-type well having a resistance sufficiently lower than that of the first well in order to prevent latch-up. FIG. 1 illustrates a semiconductor device Q2 as a P-channel type MOSFET (hereinafter, also referred to as a “PMOS”) of the CMOS circuit of the peripheral circuit and illustrates a semiconductor device Q3 as a N-channel type MOSFET (hereinafter, also referred to as an “NMOS”) of the CMOS circuit. An N-well 15 for forming the semiconductor device Q2 is formed in the semiconductor substrate 10. The main electrode of the semiconductor device Q2 is formed in the N-well 15. In addition, a P-well 14 for forming the semiconductor device Q3 is formed in the semiconductor substrate 10. The main electrode of the semiconductor device Q3 is formed in the P-well 14. The depths of the P-well 14 and the N-well 15 are in a range of, for example, 0.5 μm to 1.6 μm, and are, for example, about 1 μm. Since the depth of the second well 12 is 2 μm or more, the P-well 14 and the N-well 15 are formed in a region that is shallower than the second well 12. The size of the P-well 14 and the N-well 15 can be reduced with a sufficiently lower resistance than the first well 11 and the second well 12 making up the double-well structure.

The gate structures of the semiconductor devices Q2 and Q3 are substantially the same as that of an FET 50. The semiconductor devices Q2 and Q3 are different from the FET in terms of the gate insulating film 53. The gate insulating films (also referred to as “second gate insulating films”) of the semiconductor devices Q2 and Q3 are thinner than the gate insulating film of the FET 50 in order to enable high-speed operations and low-voltage operations of the CMOS circuit. A silicon oxide film or an oxynitride film having a film thickness of, for example, 3 nm to 9 nm is used as the second gate insulating film. On the other hand, in order to maintain the reliability of the FET 50 to which a voltage of, for example, 15 V or more is applied, the first gate insulating film is thicker than the second gate insulating film. The first gate insulating film is a silicon oxide film or an oxynitride film having a film thickness of, for example, 20 nm to 40 nm.

Furthermore, an EEPROM, a flash memory, or the like requires a high voltage generation circuit that generates a high voltage from a lower voltage. The high voltage generation circuit generates a voltage of, for example, 10 V to 15 V or more with respect to the semiconductor substrate 10. For this reason, the high voltage generation circuit typically has a booster circuit. The booster circuit is, for example, a charge pump circuit. The charge pump circuit includes a plurality of capacitors for storing electric charges and a plurality of transistors for controlling the storage of the electric charges.

A semiconductor device Q4 illustrated in FIG. 1 is an example of a high breakdown voltage transistor used in a high voltage generation circuit. The semiconductor device Q4 is an FET in which the main electrode is formed on the semiconductor substrate 10. The semiconductor device Q4 withstands a potential difference of, for example, 15 V or more with reference to the potential of the semiconductor substrate 10. For this reason, the gate insulating film 53 of the semiconductor device Q4 is thicker than the gate insulating films 53 of the semiconductor devices Q2 and Q3. The gate insulating film 53 of the semiconductor device Q4 is, for example, a silicon oxide film or an oxynitride film having a film thickness of 16 nm to 50 nm.

It is noted that, in flash memory, during the erasing of data or the writing of data, a positive voltage of 15 V or more is usually applied to the first well 11 or the gate electrode 52 of an FET 50. From this viewpoint as well, a high breakdown voltage transistor having a thicker gate insulating film than the semiconductor devices Q2 and Q3 is generally required. A voltage of 15 V or more is applied between the drain electrode of the high breakdown voltage transistor and the semiconductor substrate. For this reason, it is necessary to maintain a junction breakdown voltage and reduce the junction leakage, and a region having an impurity concentration lower than that of the first well 11, for example, a region having an impurity concentration lower than 10¹⁵ cm⁻³ is required. As this region, the semiconductor device Q4 uses the semiconductor substrate 10. As illustrated in FIG. 1, the third well 13 may be disposed between the semiconductor device Q4 and the semiconductor device Q1. In such a case, in order to prevent punch-through, it is preferable to form the third well 13 so as to surround the side surface region 121a.

A capacitor C1 illustrated in FIG. 1 is a capacitor for storing electric charges used for the charge pump circuit. When the capacitor C1 and the FETs 50 are formed on the same semiconductor substrate 10, the capacitor C1 may have a structure in which a control gate electrode 52a and a floating gate 52b face each other via a block insulating film 52c. Accordingly, it is possible to form the capacitor C1 having the floating gate 52b as the charge storage layer. The block insulating film 52c is, for example, a silicon oxide film, an oxynitride film, a stacked film of a silicon oxide film/silicon nitride film/silicon oxide film, or the like having a film thickness of 5 nm to 30 nm. On the other hand, the gate electrode 52 has a structure in which the control gate electrode 52a and the floating gate 52b are stacked without the block insulating film 52c interposed therebetween.

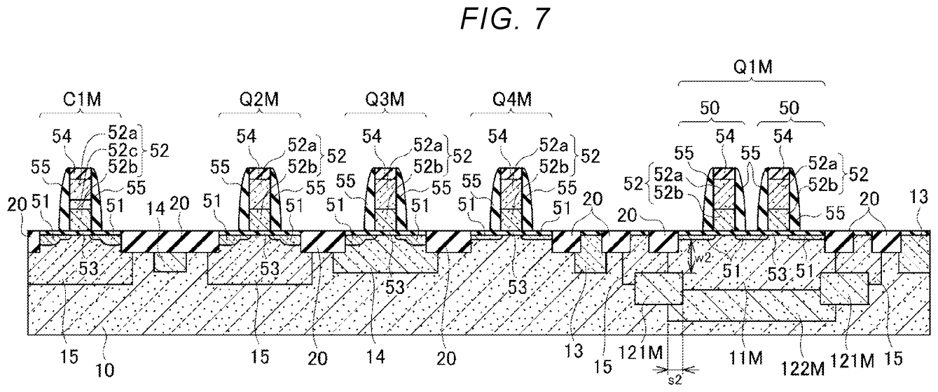

In order to compare with the semiconductor device Q1, a semiconductor device Q1M as a comparative example will be described below with reference to FIG. 7. In addition, a semiconductor device Q2M, a semiconductor device Q3M, a semiconductor device Q4M, and a capacitor C1M illustrated in FIG. 7 are comparative examples with respect to the semiconductor device Q2, the semiconductor device Q3, the semiconductor device Q4, and the capacitor C1 illustrated in FIG. 1.

As illustrated in FIG. 7, a P-well 11M which is a P-type well is surrounded by the N-well 15 which is an N-type well, a connection well 121M, and a buried well 122M. The N-well 15 surrounds the side surface of the P-well 11M. The buried well 122M is disposed below the P-well 11M. The connection well 121M connects the N-well 15 and the buried well 122M. The connection well 121M and the buried well 122M overlap in a region having a width s2 in a plan view. The upper surface of the connection well 121M is closer to the surface of the substrate 10 than the upper surface of the buried well 122M. The film thickness of the P-well 11M up to the connection well 121M is w2.

The P-well 11M and the semiconductor substrate 10 are electrically separated by the N-well 15, the connection well 121M, and the buried well 122M. For this reason, a positive voltage can be applied to the P-well 11M independently of the P-type semiconductor substrate 10. As described above, the semiconductor device Q1M has the double-well structure.

The buried well 122M making up the double-well structure needs to be deeper than the P-well 11M. In addition, in order to maintain the junction breakdown voltage of, for example, 15 V or more, the buried well 122M is formed on the P-type semiconductor substrate 10 having an impurity concentration lower than 10¹⁵ cm⁻³. In order to maintain the potential of the buried well 122M to be constant, the peak concentration of the buried well 122M is, for example, 10¹⁶ cm⁻³ or more. The buried well 122M is expanded to a depth of, for example, 2 μm or more, typically 2 μm to 4 μm. That is, the position of the PN junction boundary between the P-well 11M and the buried well 122M is at a depth of, for example, 2 μm or more. In the structure of the comparative example, the peak concentration of the buried well 122M is lower than the peak concentration of the P-well 11M. This is because, when the energy of ion implantation is increased so as to dope the semiconductor substrate 10 with the impurity ions to deep positions, the manufacturing cost increases. In order to reduce the manufacturing cost, the impurity concentration of the buried well 122M is kept low.

A plurality of the FETs 50 are arranged in the P-well 11M. The electrode diffusion layer 51 which is the source electrode and the drain electrode of each FET 50 is formed in the P-well 11M.

When the peripheral circuit of the semiconductor memory is a CMOS circuit and the FETs 50 are applied to the word line switch transistors QT used in the peripheral circuit, in order to prevent latch-up in the CMOS circuit, the P-well 14 and N-well 15 are formed at positions shallower than the buried well 122M. The P-well 14 corresponds to the region of the CMOS circuit in which the NMOS is disposed. The N-well 15 corresponds to the region of the CMOS circuit in which the PMOS is disposed.

The depth of the P-well 14 is, for example, about 1 μm. In order to prevent the punch-through through the semiconductor substrate 10 between the facing N-wells 15, the N-well 15 is formed on the semiconductor substrate 10 at a depth of, for example, about 1.5 μm. Since the N-well 15 is deep in order to prevent the punch-through, the plane design rule cannot be reduced.

In the semiconductor device Q1M of the comparative example, the N-well 15 is formed in a ring shape around the P-well 11M. The N-well 15 is an upper portion of the side surface portion of the N-type well making up the double-well structure. Since the N-well 15 is formed at the shallow position of the semiconductor substrate 10 as described above, the buried well 122M formed at the deep position of the semiconductor substrate 10 is not directly connected to the N-well 15, and the N-type region is divided by the periphery of the P-well 11M. When the N-type region is divided, the P-type region is continuous between the P-well 11M and the semiconductor substrate 10. For this reason, the connection well 121M connects the N-well 15 and the buried well 122M. The connection well 121M is formed in a ring shape around the buried well 122M. The mask pattern of the connection well 121M and the mask pattern of the buried well 122M used in the lithography process are overlapped with a margin so that the N-well 15 and the buried well 122M are securely connected via the connection well 121M.

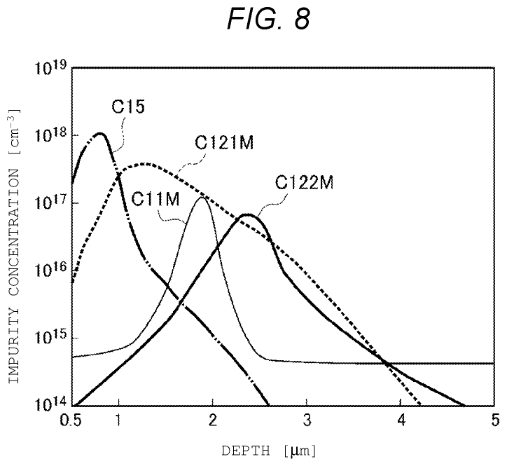

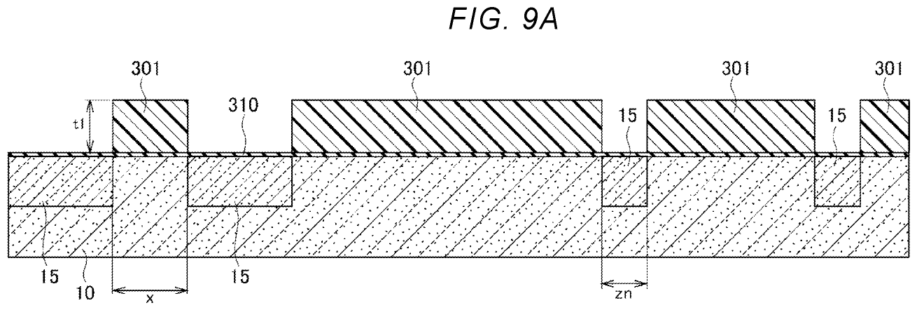

FIG. 8 illustrates the impurity concentration profile of each region of the semiconductor device Q1M. In FIG. 8, C11M is the impurity concentration of the P-well 11M, C121M is the impurity concentration of the connection well 121M, C122M is the impurity concentration of the buried well 122M, and C15 is the impurity concentration of the N-well 15.

As illustrated in FIG. 8, the connection well 121M having an impurity concentration higher than that of the P-well 11M is formed in the range between the peak concentration depth of the impurity concentration C15 of the N-well 15 and the peak concentration depth of the impurity concentration C122M of the buried well 122M. Accordingly, the P-well 11M is electrically separated from the semiconductor substrate 10.

The semiconductor device Q2M illustrated in FIG. 7 is a PMOS formed in the N-well 15. The semiconductor device Q3M is an NMOS formed in the P-well 14. The semiconductor device Q4M is an example of a high breakdown voltage transistor used in a charge pump circuit or the like. A capacitor that stores electric charges in the charge pump circuit may be used. As this capacitor, the capacitor C1M is illustrated in FIG. 7. The semiconductor devices Q2M to Q4M and the capacitor C1M have the same configurations as the semiconductor devices Q2 to Q4 and the capacitor C1, respectively.

Herein, a voltage of 0 V or more in a range of 0 V to 4 V with respect to the semiconductor substrate 10 is applied to the buried well 122M. On the other hand, a voltage in a range of, for example, −1 V to −5 V with respect to the semiconductor substrate 10 is applied to the P-well 11M so that the voltage of the P-well 11M is equal to or less than the voltage of the buried well 122M. Accordingly, even when the voltage of the main electrode 51 of an FET 50 is negative with respect to the semiconductor substrate 10, the voltage applied to the P-well 11M can be maintained so that a voltage more positive than the voltage of the P-well 11M is applied to the main electrode 51. By maintaining the voltage of the P-well 11M in this manner, the junction leakage current between the main electrode 51 and the P-well 11M is prevented, and the negative voltage with respect to the semiconductor substrate 10 can be applied to the memory cell array by the semiconductor device Q1.

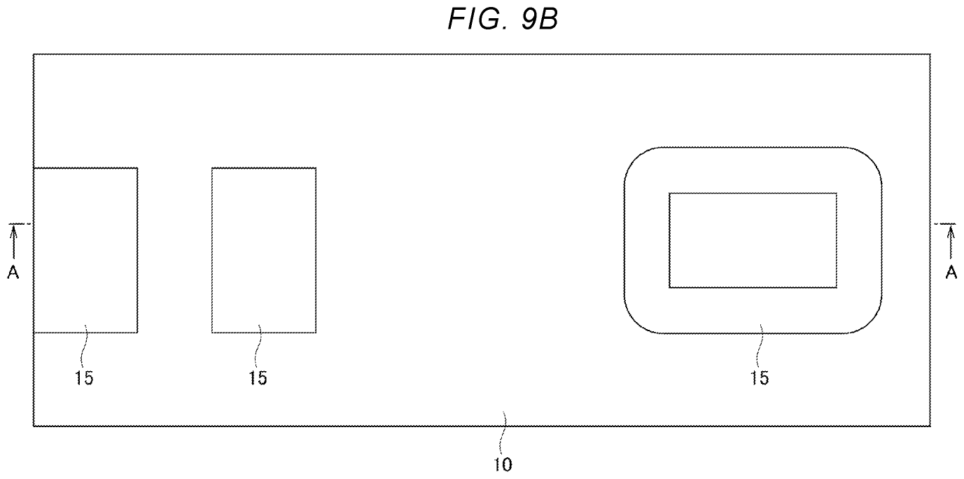

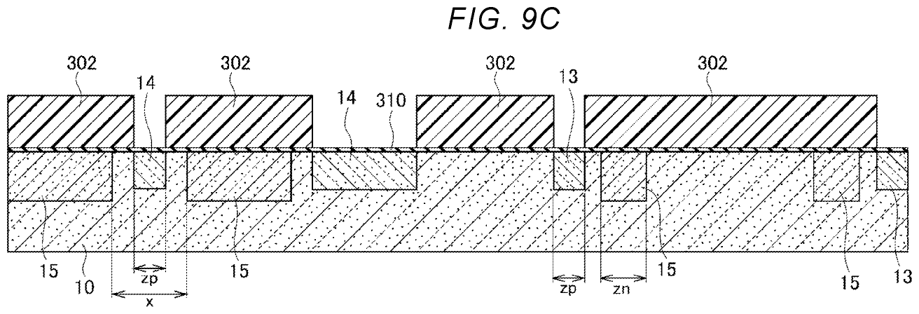

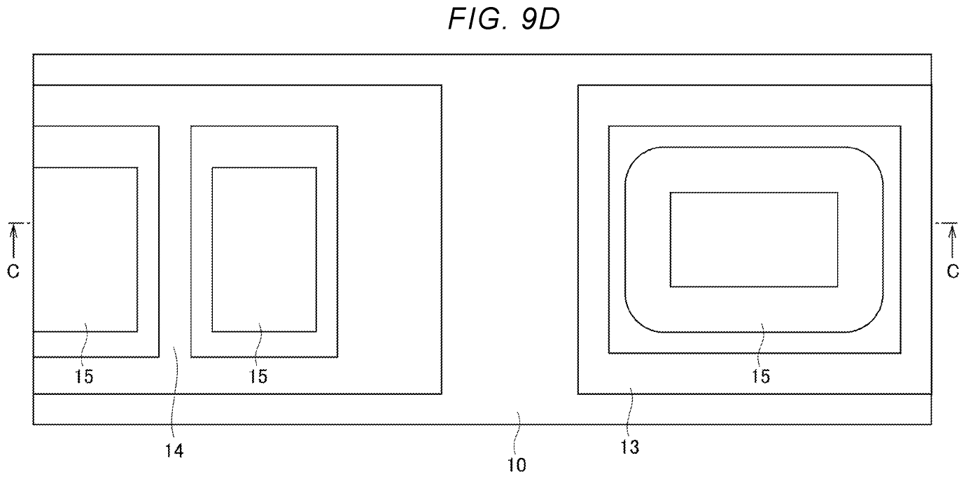

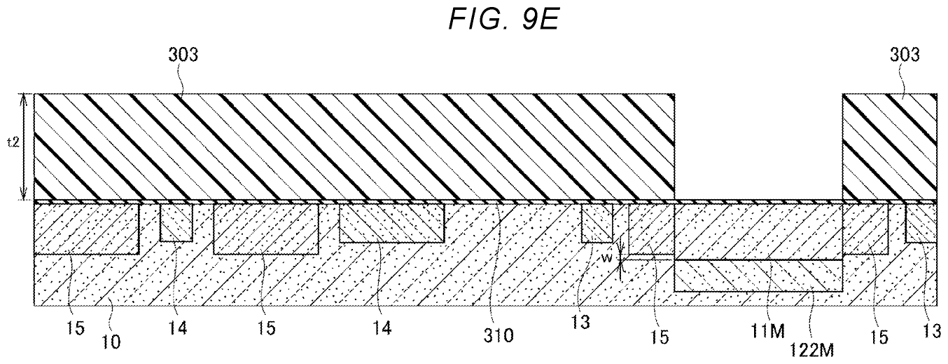

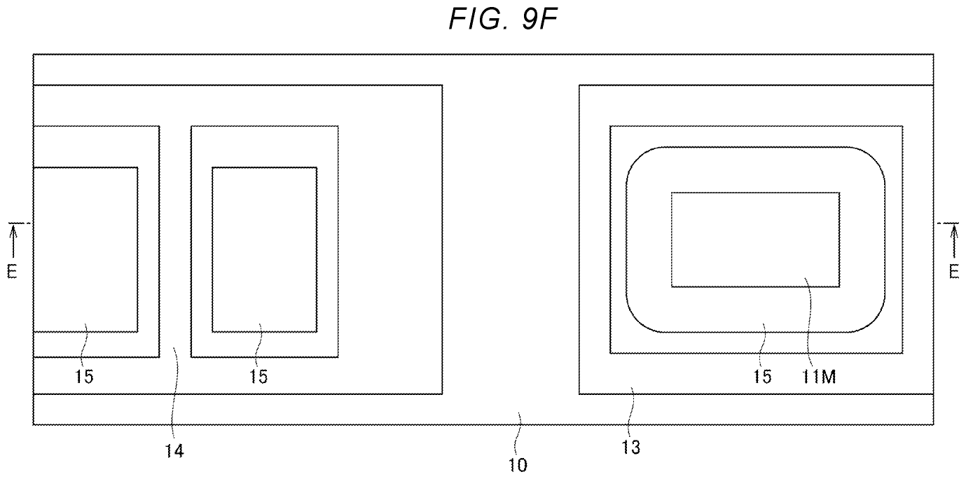

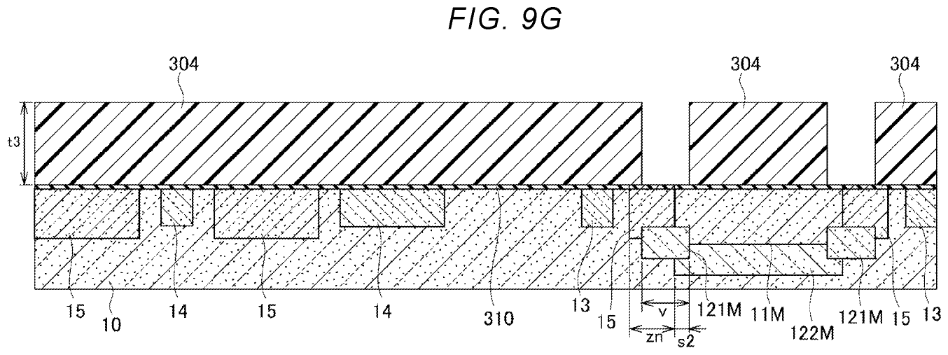

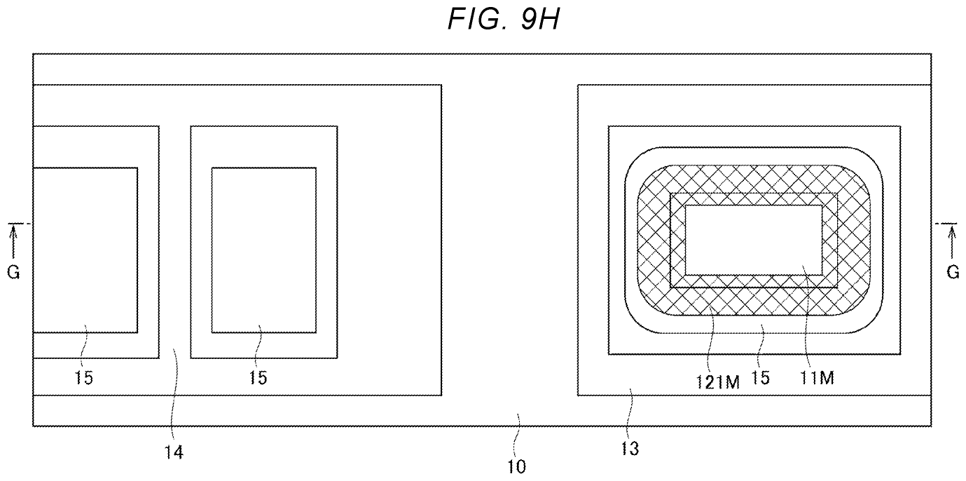

Hereinafter, a method for manufacturing the semiconductor device Q1M as the comparative example will be described with reference to FIGS. 9A to 9H, and problems in the manufacturing method will be examined.

First, as illustrated in FIG. 9A, a sacrificial oxide film 310 is formed on the semiconductor substrate 10. The film thickness of the sacrificial oxide film 310 is, for example, about 10 nm. Next, a photoresist film 301 is applied to the entire surface of the sacrificial oxide film 310. The film thickness t1 of the photoresist film 301 is, for example, 1.8 μm or more. After that, a plurality of openings is formed in the photoresist film 301 by using a photolithography technique as illustrated in FIGS. 9A and 9B. FIG. 9A is a cross-sectional view taken along the direction A-A of FIG. 9B. It is noted that, in the plan view illustrating the manufacturing method, each well is illustrated to pass through the sacrificial oxide film 310 and the photoresist film in order to make it easy to understand the positional relationship of each well.

Next, the N-well 15 is formed by doping the semiconductor substrate 10 with N-type impurities by using an ion implantation method using the photoresist film 301 as a mask. The N-type impurities are, for example, phosphorus, arsenic, antimony, and the like.

In order to form the N-type well in the deep region of the semiconductor substrate 10, a thick photoresist film is required so that the unnecessary portion is doped with the N-type impurities. However, when the photoresist film is made thick, the photoresist film may collapse, or the width of the well in a plan view may be expanded due to the problem of resolution. In FIG. 9A, the width of the N-well 15 is indicated as “zn”. In particular, when the N-well 15 is formed in common with the buried well 122M below the P-well 11M, the width zn of the N-well 15 and the distance between the N-wells 15 (illustrated as “x” in FIGS. 1 and 9A) are considerably larger than the width of the P-well 14 and the third well 13. Similarly, the width of the N-well 15 surrounding the P-well 11M is significantly wider than the width of the P-well 14. When the width of the P-type well or the width of the N-type well is wide, the miniaturization of the semiconductor device is hindered when a deep well is formed. The P-well 14 and the N-well 15 are preferably narrow in width in order to reduce the dimension of the well.

Next, after the photoresist film 301 is removed, a photoresist film 302 is applied to the entire surface of the sacrificial oxide film 310. Then, as illustrated in FIGS. 9C and 9D, a plurality of openings of the photoresist film 302 is formed by using the photolithography technique. FIG. 9C is a cross-sectional view taken along the direction C-C of FIG. 9D.

Next, the P-well 14 and the third well 13 are formed by doping the semiconductor substrate 10 with the P-type impurities by using the ion implantation method using the photoresist film 302 as a mask. The P-type impurity is, for example, boron or indium. The depth of the P-type well formed at this time can made smaller than that of the N-type well. This is because it is not necessary to form the P-well 11M and the P-well 14 by a common process. Since the depth of the P-type well is small, the energy of ion implantation can be lowered. Therefore, even when the thickness of the photoresist film 302 is made thinner than the thickness of the photoresist film 301 of 1.8 μm, the ion-implanted P-type impurities do not penetrate through the photoresist film 302. The thickness of the photoresist film 302 is, for example, 1.6 μm or less. Accordingly, the width of the third well 13 (illustrated as “zp” in FIGS. 1 and 9C) can be made smaller than the width zn of the side surface region 121a.

Next, after the photoresist film 302 is removed, a photoresist film 303 is applied to the entire surface of the sacrificial oxide film 310. Then, as illustrated in FIGS. 9E and 9F, an opening is formed in the photoresist film 303 by using the photolithography technique. FIG. 9E is a cross-sectional view taken along the direction E-E of FIG. 9F. Then, the buried well 122M is formed by doping the semiconductor substrate 10 with the N-type impurities (for example, phosphorus or arsenic) by using the ion implantation method using the photoresist film 303 as a mask. Furthermore, the P-well 11M is formed by doping the semiconductor substrate 10 with the P-type impurities (for example, boron) by using the ion implantation method using the photoresist film 303 as a mask. At this time, the buried well 122M needs to be deeper than the P-well 11M, and the buried well 122M is typically expanded at a depth of 2 μm to 4 μm. For this reason, the film thickness t2 of the photoresist film 303 is, for example, 4 μm to 7 μm.

The film thickness t2 of the photoresist film 303 is much larger than those of the photoresist film 301 and the photoresist film 302. For this reason, the cost of the photoresist member is high, and it takes time to sufficiently expose the thick photoresist film in the exposure process, so that the manufacturing cost increases.

As illustrated in FIG. 9E, the N-well 15 and the buried well 122M are not connected, and the P-well 11M and the semiconductor substrate 10 are not separated. In FIG. 9E, the depth of the separated region between the N-well 15 and the buried well 122M is indicated as “w”.

Next, after the photoresist film 303 is removed, a photoresist film 304 having a film thickness of t3 is applied to the entire surface of the sacrificial oxide film 310. Then, as illustrated in FIGS. 9G and 9H, an opening is formed in the photoresist film 304 by using the photolithography technique. FIG. 9G is a cross-sectional view taken along the direction G-G of FIG. 9H. Then, the connection well 121M is formed by doping the semiconductor substrate 10 with the N-type impurities (for example, phosphorus or arsenic) by using the ion implantation method using the photoresist film 304 as a mask. The connection well 121M is an additionally formed N-type well that is connected to the N-well 15 which is the upper portion of the side surface of the double-well structure and is connected to the buried well 122M as the lower portion of the side surface of the double-well structure. The connection well 121M is formed in a ring shape so as to be connected to the upper portion of the buried well 122M. In FIG. 9H, the connection well 121M is illustrated with hatching.

The connection well 121M needs to be formed so that the N-type impurity concentration is higher than that of the P-well 11M, which has a P-type impurity concentration higher than 10¹⁶ cm⁻³ in a depth range of 1.5 μm to 2.5 μm. As illustrated in FIG. 8, the connection well 121M is typically expanded to a depth of, for example, 2 μm or more. Even when a method of spreading impurities such as channeling of the semiconductor substrate 10 in the depth direction is used, the film thickness t3 of the photoresist film 304 needs to be large. The photoresist film 304 has a film thickness of, for example, 2 μm to 7 μm. The film thickness t3 is sufficiently larger than those of the photoresist film 301 and the photoresist film 302. For this reason, the cost of the photoresist member is high, and it takes time to sufficiently expose the thick photoresist film in the exposure process, so that the manufacturing cost increases.

Furthermore, in order to form the connection well 121M at a deep position, the photoresist film 304 cannot also decrease the minimum well width as compared with the photoresist film 301 for forming the N-wells 15 due to the problem of the resolution of the photoresist film. For this reason, the connection well 121M is formed in a process different from that of other N-type wells. As a result, as compared with the process in which the connection well 121M is not formed, the layout design in the lateral direction is expanded due to the width v of the connection well 121M. For example, in general, the width v of the connection well 121M with respect to the width zn is expanded according to the film thickness ratio of the photoresist film 301 and the photoresist film 304. As a result, there are restrictions on the reduction of the design rule of the double-well structure.

As described above, in the semiconductor device of the comparative example, the P-well 11M having the double-well structure and the semiconductor substrate 10 can be electrically separated from each other by forming the N-well 15, the connection well 121M, and the buried well 122M. However, in order to implement the double-well structure of the semiconductor device of the comparative example, a region where an N-type doped region in which N-type impurities are doped to form the connection well 121M and a P-type doped region in which P-type impurities are doped to form the P-well 11M overlap each other is generated. In FIG. 7, the width of the overlapping region where the N-type doped region and the P-type doped region overlap is indicated as s2. The width s2 is, for example, 0.1 μm to 1.0 μm.

After that, the electrode diffusion layer 51, the gate electrode 52, and the like are formed by a known manufacturing method to form the semiconductor devices Q1M to Q4M and the capacitor C1M. Furthermore, in some examples, an interlayer insulating film may be formed on the transistor.

The method for manufacturing the semiconductor device Q1M of the comparative example having the double-well structure described above results in the following issues:

(1) The connection well 121M is formed by using a photolithography technique in a process separate from that used for forming the buried well 122M. For this reason, due to the alignment margin of the mask, an N-type impurity-doped overlapping region for forming the connection well 121M is formed inside the P-type doped region for forming the P-well 11M. As a result, the distance between the electrode diffusion layer 51, which is the source electrode or drain electrode of an FET 50, and the connection well 121M is less than the distance between the buried well 122M and the electrode diffusion layer 51. Accordingly, a decrease in breakdown voltage and an increase in leakage current occur. In order to prevent this decrease in breakdown voltage, it is necessary not to place the electrode diffusion layer 51 in the near vicinity of the connection well 121M, which leads to an increase in the area of the semiconductor device. Therefore, in the semiconductor device Q1M of the comparative example illustrated in FIG. 7, it is difficult to reduce the design rules of the double-well structure to promote miniaturization.

(2) Since the connection well 121M is formed in a process separate from that of the buried well 122M, the film thickness t3 of the photoresist film 303 is, for example, 2 μm to 7 μm. This film thickness t3 is considerably larger than those of the photoresist films 301 and 302. For this reason, the cost of the photoresist material is higher, and it additionally takes extra time to sufficiently expose the thicker photoresist film in an exposure process, so that the manufacturing cost increases.

In the semiconductor device according to the first embodiment, a high breakdown voltage transistor that utilizes a double-well structure in which an N-type well is formed at a deep position, the width of the N-type well surrounding the P-type well can be reduced. For this reason, it is possible to implement the double-well structure that prevents the punch-through with adjacent elements and is advantageous for miniaturization. In addition, the manufacturing process of the N-type well on the outer side of the double-well structure can be shortened, and the number of processes and the manufacturing cost can be reduced.

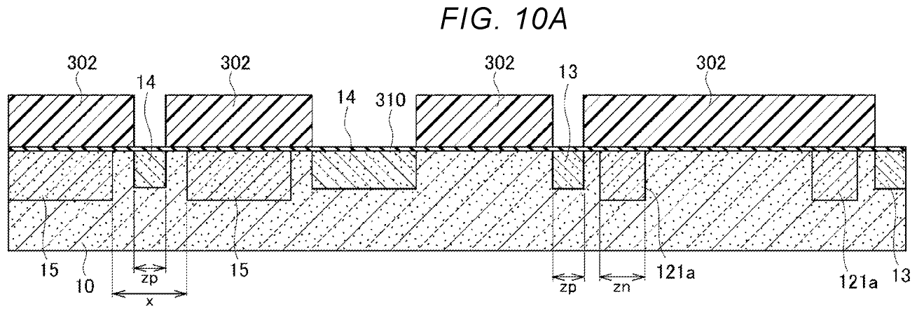

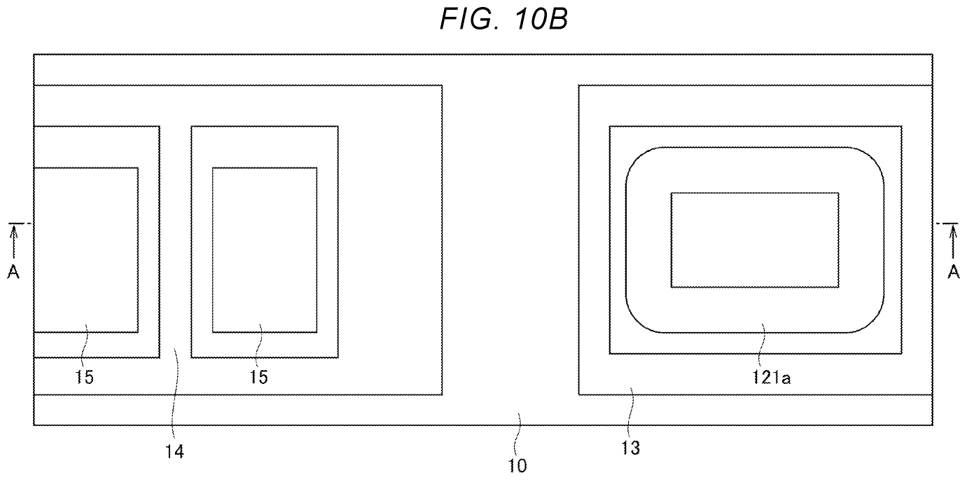

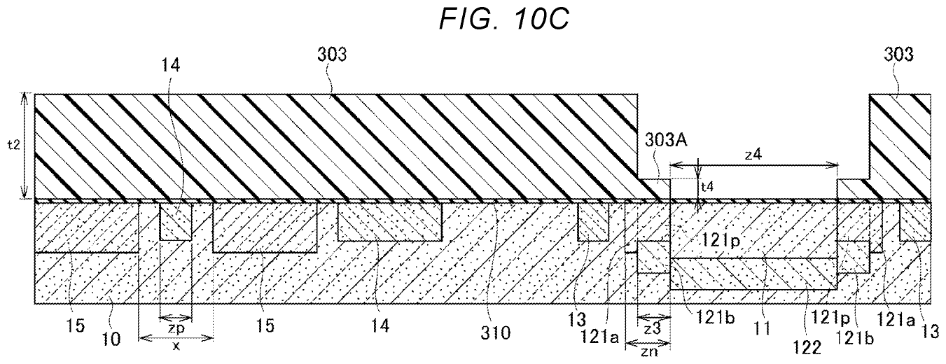

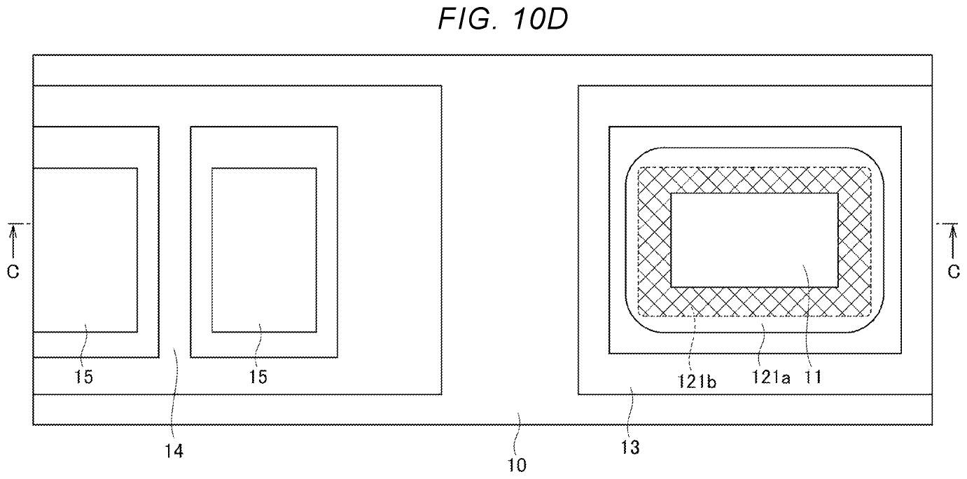

Hereinafter, a method for manufacturing the semiconductor device according to the first embodiment will be described with reference to FIGS. 10A to 10D.

First, the side surface region 121a of the N-type well and the N-well 15 are formed in the same process by using the photoresist film 302 similarly to the method described with reference to FIGS. 9A and 9B. The side surface region 121a is formed in a ring shape in a plan view so as to surround the region in which the first well 11 is formed. Next, the photoresist film 302 is applied to the entire surface of the sacrificial oxide film 310. Then, as illustrated in FIGS. 10A and 10B, a plurality of openings is formed the photoresist film 302 by using the photolithography technique. FIG. 10A is a cross-sectional view taken along the direction A-A of FIG. 10B.

Next, the P-well 14 and the third well 13 are formed by doping the semiconductor substrate 10 with the P-type impurities by using the ion implantation method using the photoresist film 302 as a mask. At this time, the depths of the P-well 14 and the third well 13 can be made smaller than the depths of the side surface region 121a and the N-well 15. This is because it is not necessary to form the P-well 14 in the same process as the first well 11. For this reason, even when the film thickness of the photoresist film 302 is made thinner than the film thickness of the photoresist film 301 (for example, 1.8 μm), the ion-implanted P-type impurities do not penetrate the photoresist film 302. The film thickness of the photoresist film 302 is, for example, 1.6 μm or less. Therefore, the width zp of the third well 13 can be made smaller than the width zn of the side surface region 121a.

Next, after the photoresist film 302 is removed, the photoresist film 303 having a film thickness of t2 is applied to the entire surface of the sacrificial oxide film 310. Then, as illustrated in FIGS. 10C and 10D, the opening is formed in the photoresist film 303 by using the photolithography technique. The film thickness t2 is, for example, 4 μm to 7 μm. FIG. 10C is a cross-sectional view taken along the direction C-C of FIG. 10D.

At this time, as illustrated in FIG. 10C, an outer edge resist 303A having a film thickness of t4 as a portion of the photoresist film 303 is left in a ring shape along the outer edge of the opening of the photoresist film 303. The outer edge resist 303A surrounds entirely the opening of the photoresist film 303. The film thickness t4 is, for example, 0.2 μm to 3 μm. A width z4 of the opening of the photoresist film 303 is, for example, 1 μm to 500 μm. In addition, the width z3 of the connection region 121b is smaller than the width of the second portion 122 and is, for example, 0.1 μm to 10 μm.

In order to implement a structure in which the height of the photoresist film 303 changes, for example, a halftone structure having a different amount of light transmission may be formed on the outer edge of the opening of the photoresist film 303. Then, a structure in which the height of the photoresist film 303 changes is created by one exposure by a known mask technique for increasing the amount of light transmission. In addition, for example, a “line/space” pattern smaller than the wavelength of light may be formed on the exposure mask. That is, the “line/space” pattern may be disposed on the outer periphery of the opening of the photoresist film 303 to reduce the amount of light transmission.

Next, the connection region 121b and the second portion 122 which is the lower portion of the double-well structure are simultaneously formed by doping the semiconductor substrate 10 with N-type impurities by using the ion implantation method using the photoresist film 303 as a mask. Furthermore, the first well 11 which is the upper portion of the double-well structure is formed by doping the semiconductor substrate 10 with the P-type impurities by using the ion implantation method using the photoresist film 303 as a mask. Accordingly, the first well 11 is formed in the semiconductor substrate 10 such that the upper portion of the side surface thereof is covered by the side surface region 121a, the lower portion of the side surface thereof is covered by the connection region 121b, and the bottom portion is covered by the second portion 122. At this time, since the second portion 122 needs to be deeper than the first well 11, the second portion 122 is formed at a depth of, for example, 2 μm to 4 μm. For this reason, the film thickness t2 of the photoresist film 303 is thick, and the film thickness t2 is, for example, 4 μm to 7 μm.

In an ion implantation process using the photoresist film 303 as a mask, the positions of the N-type impurities implanted into the semiconductor substrate 10 are shallow in the region where the outer edge resist 303A is disposed rather than the opening of the photoresist film 303 where the outer edge resist 303A is not disposed. That is, the N-type impurities are formed at shallow positions of the semiconductor substrate 10 because of the outer edge resist 303A having a film thickness of t4 that prevent the ion implantation. Accordingly, the connection region 121b connected to the second portion 122 is formed. In this manner, the connection region 121b and the second portion 122 of the second well 12 are simultaneously formed by one-time ion implantation process.

It is noted that, in the ion implantation process of forming the first well 11, the overlapping region 121p is formed by implanting the P-type impurities into the region of the side surface region 121a adjacent to the first well 11. In the region of the outer edge resist 303A, the P-type impurities are implanted into the shallow positions of the semiconductor substrate 10 by the ability of the outer edge resist 303A for preventing the ion implantation.

The width z3 of the outer edge resist 303A can be made smaller than the width zn determined by the resolution of the photoresist film 303. This is because, for example, the width of the opening of the photoresist film 303 is determined by the width z4 of the opening for forming the first well 11 having a width of 3 μm or more and z4+2×z3. The dimension of the width z3 may be reduced as compared with the dimension determined by the minimum line width.

Since the width z3 can be made smaller than the width zn, when the position of the boundary between the first well 11 and the connection region 121b and the position of the boundary between the second portion 122 and the connection region 121b are on the same line in a plan view, the distance y between the connection region 121b and the main electrode 51 of the semiconductor device Q4 in a plan view is larger than that of the comparative example. By securing the distance y in this manner, even when a voltage of 15 V or more with respect to the semiconductor substrate 10 is applied to the side surface region 121a, the punch-through from the side surface region 121a to the main electrode 51 of the semiconductor device Q4 can be prevented. For this reason, the increase in the layout area can be prevented as compared with the comparative example. In addition, by securing the distance y, for example, even when a voltage of 15 V or more with respect to the semiconductor substrate 10 is applied to the main electrode 51 of the semiconductor device Q4, the connection region 121b can prevent the punch-through at the time of, for example, 0 V.

As illustrated in FIG. 6, the peak concentration of the P-type impurity concentration C121p in the overlapping region 121p is smaller than the sum of the impurity concentration C121a in the side surface region 121a and the impurity concentration C121b in the connection region 121b at the same depth. Accordingly, the region in which the side surface region 121a and the overlapping region 121p are formed is continuously formed with the connection region 121b as the N-type region, and thus, the electrical resistance of the second well 12 can be reduced. In addition, the width zn of the side surface region 121a is wider than the width z3 of the overlapping region 121p. For this reason, even when the peak concentration of the overlapping region 121p is higher than the sum of the impurity concentration of the side surface region 121a and the impurity concentration of the connection region 121b at the same depth, the side surface region 121a and the connection region 121b are electrically connected. With such a structure, there is a degree of freedom to allow the depth of the side surface region 121a to be small, and thus, the punch-through between the side surface regions 121a may be prevented. In such a case, the overlapping region 121p is connected to the first well 11 and is formed so that the P-type region extends into the region of the N-type well. However, the P-type region and the semiconductor substrate 10 are electrically separated by the N-type well.

After that, the electrode diffusion layers 51, the gate electrodes 52, and the like are formed by a known manufacturing method to form the semiconductor devices Q1 to Q4 and the capacitor C1. Accordingly, the semiconductor device according to the first embodiment is manufactured.

As described above, the side surface region 121a and the connection region 121b are in contact with each other, and the connection region 121b and the second portion 122 are in contact with each other. For this reason, the P-type first well 11 is surrounded by the N-type second well 12 configured with the side surface region 121a, the connection region 121b, and the second portion 122. By surrounding the first well 11 with the second well 12, the first well 11 is electrically separated from the semiconductor substrate 10.

In the method for manufacturing the semiconductor device according to the first embodiment, unlike the manufacturing method of the comparative example, the second portion 122 and the connection region 121b are simultaneously formed by the same ion implantation process. That is, the recess shape of the N-type well covering the bottom surface of the first well 11 and the lower portion of the side surface is integrally formed. It is noted that, by the same ion implantation process, the overlapping region 121p is formed in the region of the N-type well at the same time as the first well 11.

The connection region 121b is formed in a self-aligned manner without alignment shift from the boundary between the second portion 122 and the connection region 121b. For this reason, the overlapping region which is generated by the manufacturing method of the comparative example and into which the N-type doped region of the P-well 11M extends can be minimized without requiring a margin for alignment shift or the like. Accordingly, the distance between the connection region 121b and the electrode diffusion layer 51 can be made wider than that in the comparative example. Therefore, it is possible to prevent a decrease in breakdown voltage and an increase in leakage current between the connection region 121b and the source electrode or drain electrode of each FET 50. In addition, it is not necessary to have a margin for alignment shift of the mask used in the photolithography technique. For this reason, with the semiconductor device Q1, the FET 50 can be provided in the vicinity of the connection region 121b as compared with the comparative example, and the layout area can be reduced.

It is noted that the N-type impurity concentration in the connection region 121b is higher than, for example, the P-type impurity concentration in the first well 11 formed in a depth range of 1.5 μm to 2.5 μm. Since the connection region 121b is formed by the same ion implantation process as the second portion 122, the peak concentration of the second portion 122 is higher than the peak concentration of the first well 11 at a depth of 1 μm or less. This point is different from the semiconductor device Q1 and the comparative example. As illustrated in FIG. 6, by forming the connection region 121b to be shallower than the second portion 122 and forming the peak concentration of the connection region 121b to be higher than the peak concentration of the first well 11, the first well 11 and the semiconductor substrate 10 can be electrically separated from each other by the connection region 121b.

The method for manufacturing the semiconductor device Q1 described above does not require the manufacturing process of the connection well 121M, which is required in the manufacturing method of the comparative example. That is, in the manufacturing method of the comparative example, it is necessary to form the connection well 121M having a higher N-type impurity concentration than the P-type impurity concentration of the first well 11 in a depth range of 1.5 μm to 2.5 μm. On the other hand, in the method for manufacturing the semiconductor device Q1, a process of forming and exposing the photoresist film having a film thickness larger than those of the photoresist films 301 and 302 for forming the connection well 121M and the ion implantation process for additionally forming the N-type well are not required. Therefore, according to the method for manufacturing the semiconductor device Q1, the photoresist member with the high cost and the time-consuming process for sufficiently exposing the thick photoresist film are unnecessary, so that the manufacturing cost can be reduced.

<Modified Example>

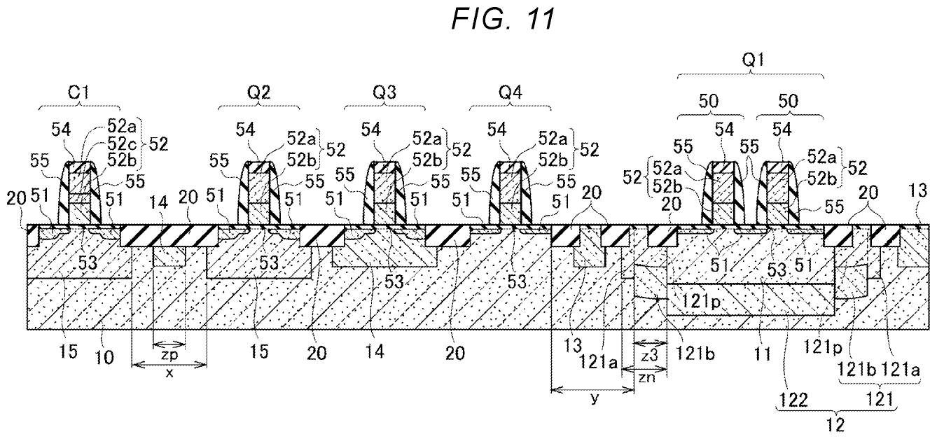

FIG. 11 illustrates a configuration of a semiconductor device Q1 according to a modified example of the first embodiment. In the semiconductor device Q1 illustrated in FIG. 11, the connection region 121b has upper and bottom surfaces each curving towards the surface of the semiconductor substrate 10 as the distance from the first well 11 increases. For this reason, it is possible to prevent a decrease in breakdown voltage due to the shape effect, which occurs at the boundary between the second well and the semiconductor substrate 10 due to the concentration of the electric field on the corner portion of the side surface of the connection region 121b.

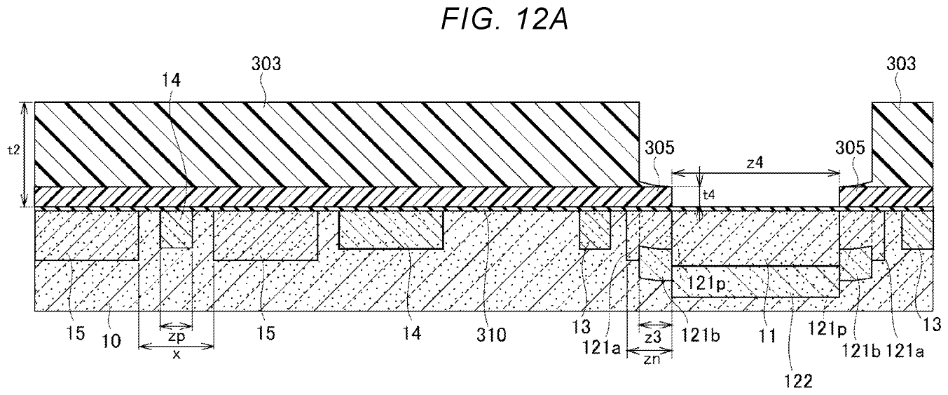

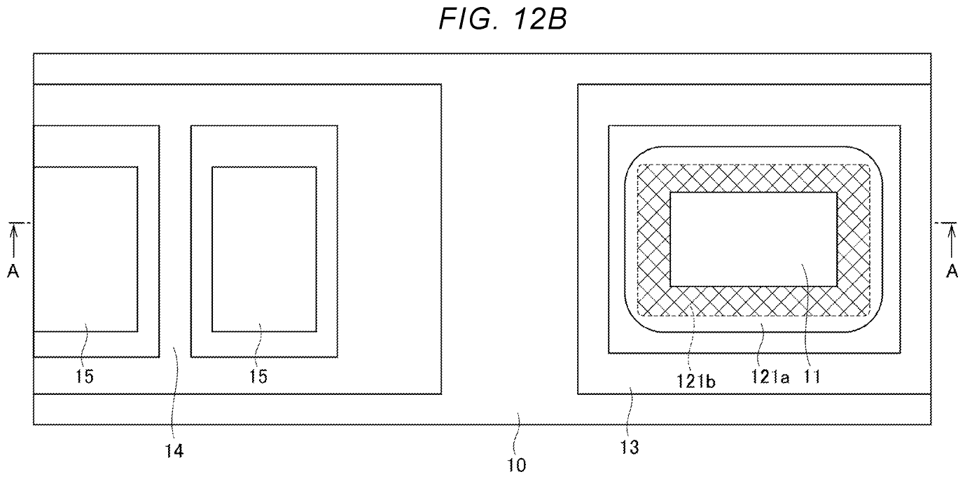

A method for manufacturing the semiconductor device Q1 illustrated in FIG. 11 will be described below with reference to FIGS. 12A to 12B. FIG. 12A is a cross-sectional view corresponding to FIG. 10C, and since the manufacturing process prior thereto is the same as that of the semiconductor device Q1 illustrated in FIG. 1, the description thereof will be omitted. FIG. 12A is a cross-sectional view taken along the direction A-A of FIG. 12B.

After a photoresist film 305 and the photoresist film 303 are sequentially applied to the entire surface of the sacrificial oxide film 310, as illustrated in FIGS. 12A and 12B, an opening is formed in the photoresist film 305 and the photoresist film 303 by using the photolithography technique. At this time, the photoresist film 305 having a film thickness of t4 is left in a ring shape along the outer edge of the opening of the photoresist film 303. The film thickness t4 is, for example, 0.2 μm to 2 μm. The width z4 of the opening of the photoresist film 305 is, for example, 1 μm to 500 μm. In addition, the width z3 of the connection region 121b is smaller than the width zn of the side surface region 121a and is, for example, 0.1 μm to 10 μm.

In order to allow the photoresist film 305 to remain in a ring shape along the outer edge of the opening of the photoresist film 303, for example, the photoresist film 305 having an exposure sensitivity or a resist dissolution rate of a photosensitized portion by development lower than that of the photoresist film 303 is used. Accordingly, a structure in which the photoresist film 305 is left along the outer edge of the opening of the photoresist film 303 can be created by one exposure. In such a case, since the step difference of the photoresist film is formed by devising the photoresist film, a low-cost chrome mask or the like can be used as a mask for exposure in the lithography process. Since a mask having a low resolution can be used, the cost of producing the mask can be reduced.

In the semiconductor device Q1 illustrated in FIG. 11, the upper and bottom surfaces of the connection region 121b approach the surface of the semiconductor substrate 10 as the distance from the first well 11 increases. As illustrated in FIG. 12A, this structure is implemented by adjusting the development of the photoresist film 303 so as to have a shape in which the film thickness of the remaining photoresist film 303 becomes small toward the inside of the opening of the photoresist film 303. The opening of the photoresist film 303 includes a portion of the photoresist film 303 having such a shape. By the ion implantation using the photoresist film 303 in which the outer edge of the opening has such a portion, the depth of the doped impurities can be made shallow from the surface of the semiconductor substrate as the distance from the first well 11 increases.

Next, the second portion 122 which is the lower portion of the double-well structure is formed by doping the semiconductor substrate 10 with the N-type impurities by using the ion implantation method using the photoresist stacked film of the photoresist film 305 and the photoresist film 303 as a mask. Furthermore, the first well 11 which is the upper portion of the double-well structure is formed by doping the semiconductor substrate 10 with the P-type impurities by using the ion implantation method using a photoresist stacked film as a mask. At this time, since the second portion 122 needs to be deeper than the first well 11, the second portion 122 is formed at a depth of, for example, 2 μm to 4 μm. For this reason, the thickness t2 of the photoresist stacked film is thick, and the film thickness t2 is, for example, 4 μm to 7 μm.

In this ion implantation process, in the region where the photoresist film 305 is left in the opening of the photoresist film 303, the positions of the N-type impurities implanted into the semiconductor substrate 10 become shallow because of the photoresist film 305 that prevent the ion implantation, so that the connection region 121b is formed. In addition, in the region where the photoresist film 305 is left in the opening of the photoresist film 303, the positions of the P-type impurities implanted into the semiconductor substrate 10 become shallow because of the photoresist film 305 that prevent the ion implantation. The overlapping region 121p is formed by implanting the P-type impurities into the region of the side surface region 121a adjacent to the first well 11.

After that, the electrode diffusion layers 51, the gate electrodes 52, and the like are formed by a known manufacturing method to form the semiconductor devices Q1 to Q4 and the capacitor C1. Accordingly, the semiconductor device Q1 illustrated in FIG. 11 is manufactured. It is noted that, since the characteristics of the impurity concentration profile by the ion implantation are the same as those in FIG. 6, the description thereof will be omitted.

### Second Embodiment

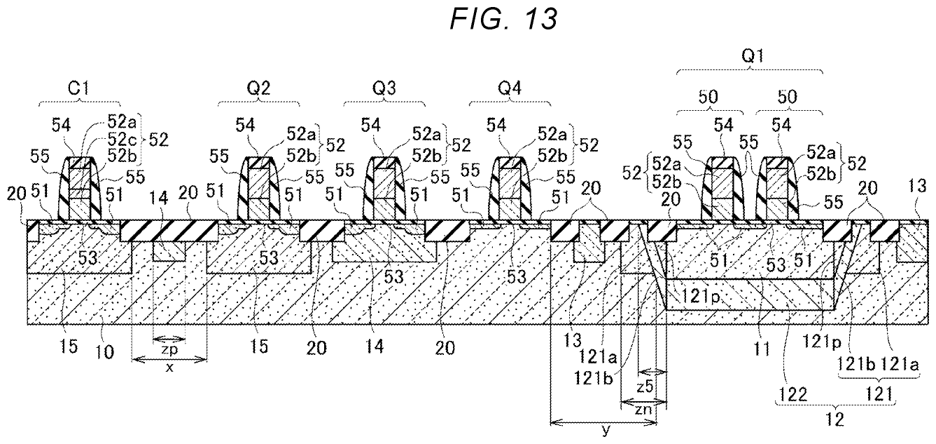

FIG. 13 illustrates a configuration of a semiconductor device Q1 according to a second embodiment. The semiconductor device Q1 illustrated in FIG. 13 is different from the first embodiment in terms of shapes of the connection region 121b and the overlapping region 121p. Others are substantially the same as those in the first embodiment, and thus, duplicate description will be omitted.

In the semiconductor device Q1 illustrated in FIG. 13, the connection region 121b approaches the surface of the semiconductor substrate 10 as the distance from the first well 11 increases. The boundary between the connection region 121b and the semiconductor substrate 10 is an inclined surface that gradually approaches the surface of the semiconductor substrate 10. This inclined surface has no corner portions where the angle of inclination changes abruptly. For this reason, the reduction in breakdown voltage due to the shape effect, which occurs at the boundary between the second well 12 and the semiconductor substrate 10 due to the concentration of the electric field on the corner portion of the side surface of the connection region 121b, can be further prevented than Q1 illustrated in FIG. 11.

The depth of the connection region 121b of the semiconductor device Q1 illustrated in FIG. 13 gradually becomes shallow toward the surface of the semiconductor substrate 10 such that the connection region is connected to the second portion 122. In addition, the connection region 121b is not formed outside the side surface region 121a in a plan view. For this reason, when the position of the boundary between the first well 11 and the connection region 121b and the position of the boundary between the second portion 122 and the connection region 121b are on the same line in a plan view, the distance y from the connection region 121b to the main electrode 51 of the semiconductor device Q4 can be made larger than that of the comparative example. Accordingly, even when a voltage of 15 V or more with respect to the semiconductor substrate 10 is applied to the side surface region 121a, the punch-through from the connection region 121b to the main electrode of the semiconductor device Q4 can be prevented. In addition, the punch-through from the main electrode 51 of the semiconductor device Q4 to the connection region 121b can be prevented.

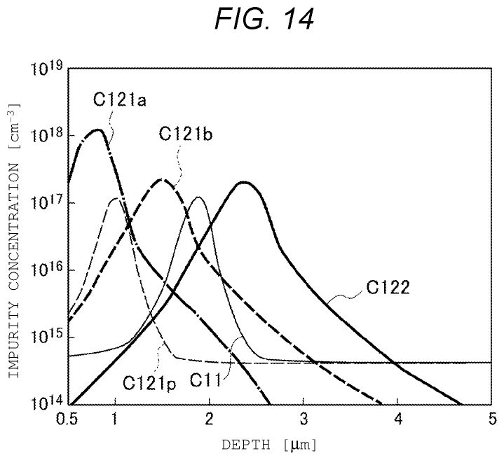

Also in the semiconductor device Q1 illustrated in FIG. 13, it is necessary to form the connection region 121b having the N-type impurity concentration higher than the P-type impurity concentration of the first well 11. FIG. 14 illustrates an example of the impurity concentration profile of the semiconductor device Q1 illustrated in FIG. 13. Similar to FIG. 6, C11 and C121p are the P-type impurity concentrations of the first well 11 and the overlapping region 121p, respectively, and C121a, C121b, and C122 are the N-type impurity concentrations of the side surface region 121a, the connection region 121b, and the second portion 122, respectively. As illustrated in FIG. 14, the peak concentration of the connection region 121b formed shallower than the second portion 122 can be made higher than the peak concentration of the first well 11, and the periphery of the P-type first well 11 can be covered with the N-type second well 12.

In addition, in the semiconductor device Q1 illustrated in FIG. 13, when the relative positional relationship between the connection region 121b and the overlapping region 121p is maintained, the connection region 121b extends towards the surface of the semiconductor substrate 10 while contacting the surface of the side surface region 121a. In the semiconductor device Q1 illustrated in FIG. 13, the connection region 121b is formed in a self-aligned manner between the overlapping region 121p and the semiconductor substrate 10. For this reason, with the semiconductor device Q1 according to the second embodiment, the first well 11 and the semiconductor substrate 10 can be electrically separated by the side surface region 121a, the connection region 121b, and the second portion 122 more completely than the semiconductor device Q1 according to the first embodiment.

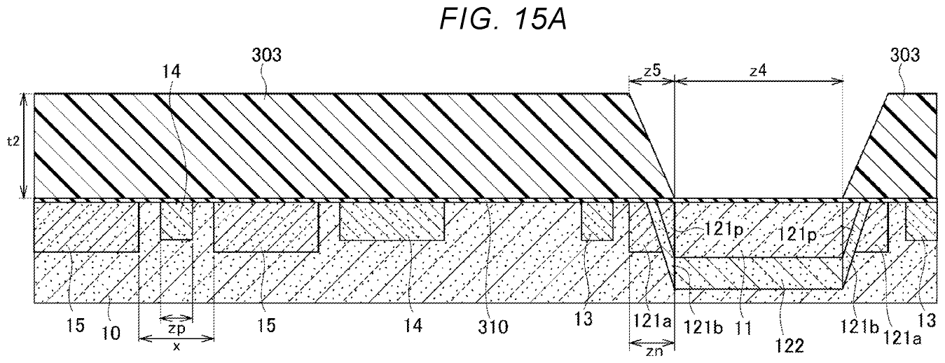

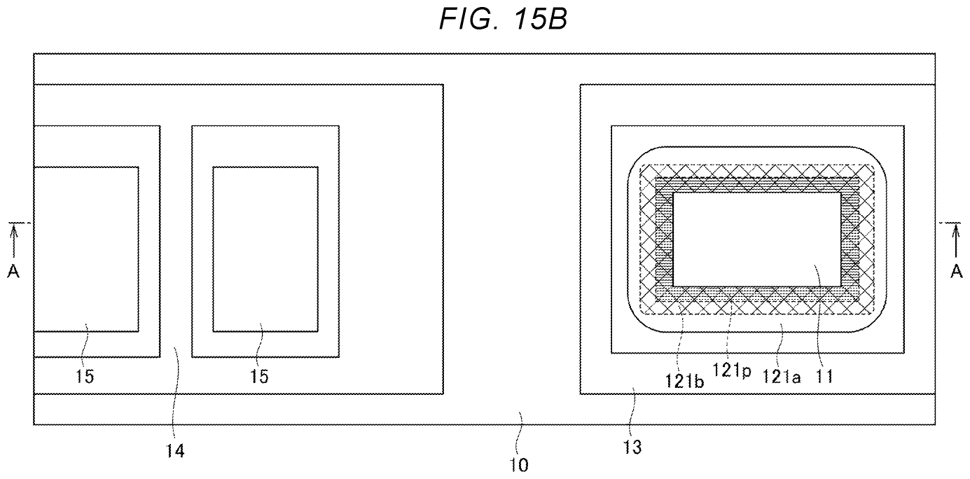

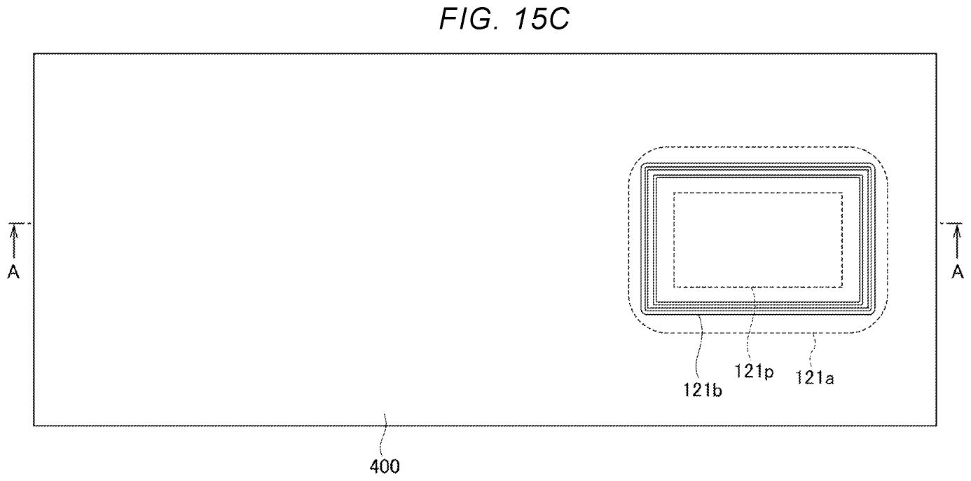

Hereinafter, an example of a method for manufacturing the semiconductor device according to the second embodiment will be described with reference to FIGS. 15A to 15C. FIG. 15A is a cross-sectional view corresponding to FIG. 10C, and since the manufacturing process prior thereto is the same as that of the semiconductor device Q1 illustrated in FIG. 1, the description thereof will be omitted. FIG. 15A is a cross-sectional view taken along the direction A-A of FIG. 15B.

As illustrated in FIG. 15A, after applying the photoresist film 303 having a film thickness of t2 to the entire surface of the sacrificial oxide film 310, an opening is formed in the photoresist film 303 by using a photolithography technique. The film thickness t2 is, for example, 4 μm to 7 μm. As illustrated in FIG. 15A, a region (hereinafter, referred to as a “tapered region”) provided with an inclination (taper) is formed in the opening of the photoresist film 303 so that the film thickness of the photoresist film 303 gradually increases from the center of the opening toward the outside. The width z4 of the bottom portion of the opening of the photoresist film 303 is, for example, 0.1 μm to 10 μm. The film thickness t2 of the photoresist film 303 is, for example, 4 μm to 7 μm.

In order to form the tapered region in the opening of the photoresist film 303, for example, light absorption in a thick photoresist film is used. In the thick photoresist film, since the amount of light transmission decreases from the upper portion toward the lower portion of the photoresist film, the amount of exposure also decreases from the upper portion of the photoresist film toward the lower portion of the photoresist film. For this reason, the tapered region can be formed in the opening of the photoresist film. In addition, the photoresist film 303 having a higher photosensitivity toward the upper portion by changing the composition in the thickness direction may be used.

It is noted that, even in the development after exposure, in the case where a thick photoresist film is used, the component eluted from the upper portion of the photoresist film increases, and the photoresist film is likely to remain in the lower portion. The tapered region may be formed in the opening of the photoresist film 303 by using this method.

In addition, as illustrated in FIG. 15C, in the exposure mask 400 of the photoresist film 303, a “line/space” pattern may be formed in a range from the connection region 121b to the overlapping region 121p with dimensions smaller than the light wavelength. The “line/space” pattern is a pattern in which line portions that block light and space portions that transmit light are alternately arranged. The space ratio of the “line/space” pattern is increased from the connection region 121b toward the overlapping region 121p. By using such an exposure mask 400, the amount of exposure can be increased from the side surface region 121a toward the overlapping region 121p. By using an inexpensive mask material such as a chrome mask as the mask material of the exposure mask 400 without using a partially transparent material, the production cost of the exposure mask 400 can be reduced. In addition, the tapered region may be formed in the opening of the photoresist film 303 by appropriately combining the above methods.

A width z5 of the tapered region of the photoresist film 303 can be set to a value smaller than the width determined by the resolution of the photoresist film 303. The width of the opening of the photoresist film 303 is determined by z4+2×z5 with respect to the width z4 of the opening of the first well 11 having a width of, for example, 3 μm or more. Therefore, the size of the width z5 can be reduced from the dimension determined by the minimum line width.

The second portion 122 which is the lower portion of the double-well structure is formed by doping the semiconductor substrate 10 with N-type impurities by using the ion implantation method using the photoresist film 303 as a mask. Furthermore, the first well 11 which is the upper portion of the double-well structure is formed by doping the semiconductor substrate 10 with the P-type impurities by using the ion implantation method using the photoresist film 303 as a mask.

In this ion implantation process, in the tapered region of the photoresist film 303, the positions of the N-type impurities implanted into the semiconductor substrate 10 gradually become shallow because of the tapered region preventing the ion implantation, so that the connection region 121b is formed. In addition, in the tapered region of the photoresist film 303, the positions of the P-type impurities implanted into the semiconductor substrate 10 become shallow because of the tapered region preventing the ion implantation. The P-type impurities are implanted into the region of the side surface region 121a adjacent to the first well 11, and thus, the overlapping region 121p is formed.

After that, the electrode diffusion layers 51, the gate electrodes 52, and the like are formed by a known manufacturing method to form the semiconductor devices Q1 to Q4 and the capacitor C1. Accordingly, the semiconductor device Q1 illustrated in FIG. 13 is manufactured. It is noted that, since the characteristics of the impurity concentration profile by the ion implantation are the same as those in FIG. 6, the description thereof will be omitted.

<Modified Example>

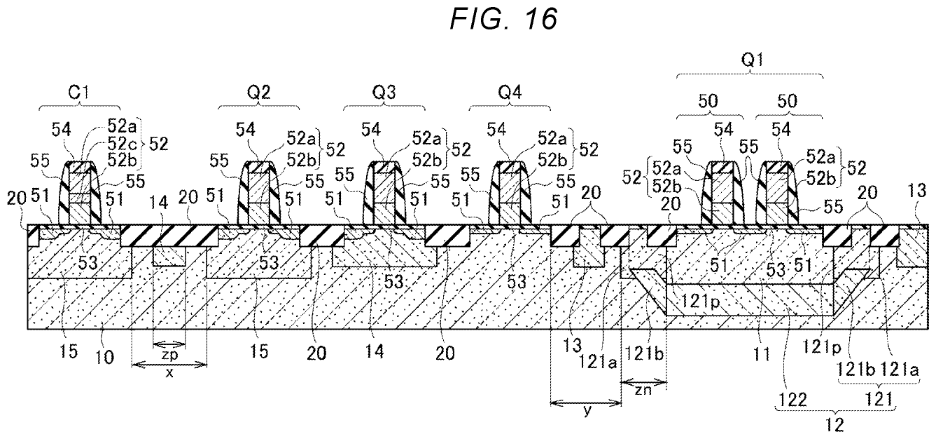

FIG. 16 illustrates a configuration of a semiconductor device Q1 according to a modified example of the second embodiment. In the semiconductor device Q1 illustrated in FIG. 16, the connection region 121b approaches the surface of the semiconductor substrate 10 as the distance from the first well 11 increases. However, the end portion of the connection region 121b does not reach the surface of the semiconductor substrate 10 and is located inside the side surface region 121a. By disposing the connection region 121b, even when the width of the side surface region 121a is reduced and the width of the connection region 121b is reduced, it is possible to prevent an increase in the angle of the inclined surface at the boundary between the connection region 121b and the semiconductor substrate 10. For this reason, it is possible to prevent the electric field concentration generated in the connection region 121b due to the shape effect at the boundary between the second well 12 and the semiconductor substrate 10.

It is noted that, at the position where the end portion of the connection region 121b is located inside the side surface region 121a, the side surface region 121a faces the semiconductor substrate 10. For this reason, even in a structure in which the end portion of the connection region 121b is located inside the side surface region 121a, the breakdown voltage characteristics of the second well 12 and the semiconductor substrate 10 are not deteriorated.

Due to the shape of the connection region 121b of the semiconductor device Q1 illustrated in FIG. 16, the decrease in breakdown voltage due to the shape effect caused by the electric field concentration at the corner portion of the connection region 121b is further prevented. In addition, the depth of the connection region 121b of the semiconductor device Q1 illustrated in FIG. 16 more gradually becomes shallow toward the surface of the semiconductor substrate 10. The connection region 121b is formed by the same ion implantation process as the second portion 122. The overlapping region 121p is formed in the side surface region 121a by the same ion implantation process as the first well 11.

In addition, in the semiconductor device Q1 illustrated in FIG. 16, when the relative positional relationship between the connection region 121b and the overlapping region 121p is maintained, the connection region 121b extends towards the surface of the semiconductor substrate 10 so as to reach the inside of the side surface region 121a. With the semiconductor device Q1 illustrated in FIG. 16, the amount of change of the connection region 121b in the depth direction can be made smaller than that of the semiconductor device Q1 illustrated in FIG. 13.

Also in the semiconductor device Q1 illustrated in FIG. 16, the connection region 121b is formed in a self-aligned manner between the overlapping region 121p and the semiconductor substrate 10. For this reason, the first well 11 and the semiconductor substrate 10 can be electrically separated by the side surface region 121a, the connection region 121b, and the second portion 122.

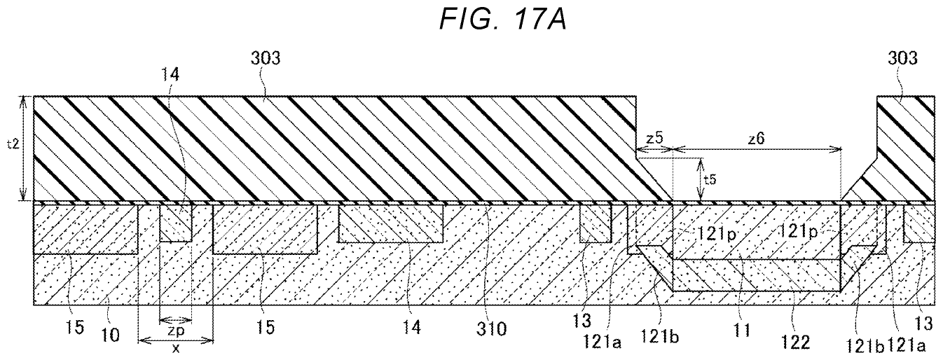

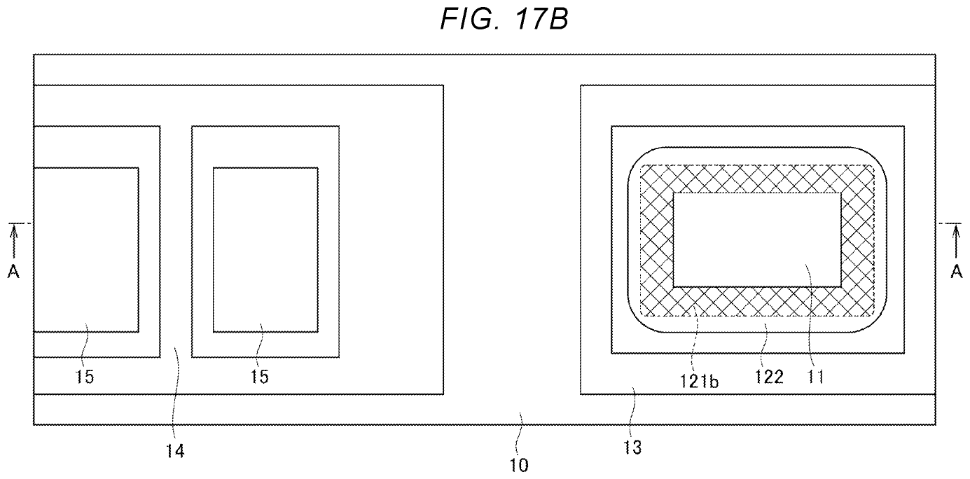

Hereinafter, a method for manufacturing the semiconductor device Q1 according to the modified example of the second embodiment will be described with reference to FIGS. 17A to 17B. FIG. 17A is a cross-sectional view corresponding to FIG. 10C, and since the manufacturing process prior thereto is the same as that of the semiconductor device Q1 illustrated in FIG. 1, the description thereof will be omitted. FIG. 17A is a cross-sectional view taken along the direction A-A of FIG. 17B.

As illustrated in FIG. 17A, after the photoresist film 303 having a film thickness of t2 is applied to the entire surface of the sacrificial oxide film 310, an opening is formed in the photoresist film 303 by using a photolithography technique. The film thickness t2 is, for example, 4 μm to 7 μm. As illustrated in FIG. 17A, a tapered region in which the film thickness of the photoresist film 303 gradually increases from the center of the opening toward the outside is formed in the opening of the photoresist film 303. However, as illustrated in FIG. 17A, an inclined surface of the tapered region does not reach the upper surface of the photoresist film 303 and intersects the side surface of the opening perpendicular to the upper surface at an intermediate point. That is, the tapered region is formed in a lower portion of the opening of the photoresist film 303 along the outer periphery of the opening. The width z5 of the tapered region is, for example, 0.1 μm to 10 μm. A height t5 of the tapered region is, for example, 0.2 μm to 3 μm.

In order to form the tapered region as illustrated in FIG. 17A in the photoresist film 303, for example, a composition of the photoresist film 303 in the thickness direction may be changed. That is, the photoresist film 303 in which the photosensitivity becomes higher toward the upper portion in the range up to the height t5 and the photosensitivity is constant above the height t5 may be used. In addition, even in the development after the exposure, in the case where a thick photoresist film is used, since the component eluted from the upper portion of the photoresist film increases, the photoresist film is likely to remain in the lower portion. The tapered region may be formed in the opening of the photoresist film 303 by using this method. Alternatively, as described with reference to FIG. 15C, the exposure mask with the “line/space” pattern may be used.

The width z5 of the tapered region can be set to a value smaller than the width determined by the resolution of the photoresist film 303. The width of the opening of the photoresist film 303 is determined by z6+2×z5 with respect to a width z6 of the opening of the connection region 121b having a width of, for example, 3 μm or more. In this manner, the size of the width z5 can be reduced from the dimension determined by the minimum line width.

The second portion 122 which is the lower portion of the double-well structure is formed by doping the semiconductor substrate 10 with N-type impurities by using the ion implantation method using the photoresist film 303 as a mask. Furthermore, the first well 11 which is the upper portion of the double-well structure is formed by doping the semiconductor substrate 10 with the P-type impurities by using the ion implantation method using the photoresist film 303 as a mask.

In this ion implantation process, in the tapered region of the photoresist film 303, the positions of the N-type impurities implanted into the semiconductor substrate 10 become shallow because of the tapered region preventing the ion implantation, so that the connection region 121b is formed. In addition, in the tapered region of the photoresist film 303, the positions of the P-type impurities implanted into the semiconductor substrate 10 become shallow because of the tapered region preventing the ion implantation. P-type impurities are implanted into the region of the side surface region 121a adjacent to the first well 11, and the overlapping region 121p is formed.

After that, the electrode diffusion layers 51, the gate electrodes 52, and the like are formed by a known manufacturing method to form the semiconductor devices Q1 to Q4 and the capacitor C1. Accordingly, the semiconductor device Q1 illustrated in FIG. 16 is manufactured. It is noted that, since the characteristics of the impurity concentration profile by the ion implantation are the same as those in FIG. 6, the description thereof will be omitted.

(Other Embodiments)

It is noted that the present disclosure is not limited to the above embodiments and modified examples. For example, as a method for forming the element separator and the insulating film, other methods of converting silicon into a silicon oxide film or a silicon nitride film, for example, a method of implanting oxygen ions into a deposited silicon or a method of oxidizing a deposited silicon may be used. In addition, as the charge storage layer, a titanium dioxide (TiO₂) film, an aluminum oxide (Al₂O₃) film, a tantalum oxide film, a strontium titanate film, a barium titanate film, a lead zirconium titanate film, or a stacked film thereof may be used.

In addition, although a P-type Si substrate is used as the semiconductor substrate 10, another single-crystal semiconductor substrate containing silicon such as silicon germanium (SiGe) mixed crystal and silicon germanium carbon (SiGeC) mixed crystal may be used instead. In addition, as each gate electrode 52, a silicide of SiGe mixed crystal, SiGeC mixed crystal, TiSi, NiSi, CoSi, silicated tantalum (TaSi), WSi, MoSi, or the like may be used. Alternatively, a metal such as polyside, titanium (Ti), aluminum (Al), copper (Cu), TiN, or tungsten (W) or the like may be used for the gate electrode 52. The gate electrode 52 may be polycrystalline or may have a stacked structure of the above-mentioned metals. In addition, amorphous Si, amorphous SiGe, or amorphous SiGeC may be used for the gate electrode 52, or a stacked structure thereof may be used.

In addition, although the NAND-type memory cell is exemplified as a memory cell, the semiconductor device Q1 may be used for the peripheral circuit of the semiconductor memory in any type of memory cell. For example, the memory cell may be any one of a NOR-type memory cell, an AND-type memory cell, and a virtual ground type memory cell. In addition, the memory cell may be a MONOS (Metal Oxide Nitride Oxide Silicon) type memory cell that stores electric charges in the insulating film, and the memory cell may be a memory cell in which the gate electrode has a floating gate.

In addition, for clarifying the description, the semiconductor devices Q1 to Q4 and the capacitor C1 are illustrated in the same cross section, but it is not necessary to form all the semiconductor elements in the same cross section, and each semiconductor element may be formed on the corresponding well. For example, the capacitor C1 may not be formed. In such a case, the gate electrodes 52 of the semiconductor devices Q1 to Q4 may not be divided into the control gate electrodes 52a and the floating gates 52b.

In addition, although the above description is made based on the example in which the semiconductor device Q1 is applied to the peripheral circuit of the semiconductor memory, the semiconductor device Q1 may be applied to a semiconductor integrated circuit device having a built-in semiconductor memory. For example, the semiconductor device Q1 may be applied to a processor, a system LSI, or the like.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device for controlling memory cell transistors, the semiconductor device comprising:
a semiconductor substrate of a first conductivity type;
a first well of the first conductivity type in the substrate;
a second well of a second conductivity type that electrically separates the first well from the substrate and includes:
a first portion surrounding a side surface of the first well, and
a second portion contacting a bottom portion of the first well and having a side surface contacting a side surface of the first portion;
a third well of the first conductivity type in the substrate, the third well surrounding the first portion of the second well but spaced therefrom; and
a first transistor that includes a gate electrode facing the first well via a first insulating film, wherein
a bottom surface of the first portion of the second well is closer to a surface of the substrate than a bottom surface of the second portion of the second well.

2. The semiconductor device according to claim 1, wherein the first portion of the second well includes a side surface region facing a side surface of the third well and a connection region between the side surface region and the second portion of the second well.

3. The semiconductor device according to claim 2, wherein an upper portion of the connection portion is between the side surface of the first well and the side surface region of the second well.

4. The semiconductor device according to claim 2, wherein a bottom surface of the side surface region is closer to the surface of the substrate than a bottom surface of the connection region.

5. The semiconductor device according to claim 1, wherein the bottom surface of the first portion of the second well is curved.

6. The semiconductor device according to claim 5, wherein the curved bottom surface approaches the surface of the substrate as a distance from the first well increases.

7. The semiconductor device according to claim 1, wherein the bottom surface of the first portion of the second well is a flat surface that is inclined with respect to the surface of the substrate so as to approach the surface of the semiconductor substrate as a distance from the first well increases.

8. The semiconductor device according to claim 7, wherein the first portion of the second well includes:
a side surface region facing a side surface of the third well, and
a connection region connecting the side surface region of the first portion of the second well and the second portion of the second well and including the inclined bottom surface.

9. The semiconductor device according to claim 8, wherein the inclined bottom surface contacts an entire side surface of the side surface region and reaches the surface of the substrate.

10. The semiconductor device according to claim 8, wherein the inclined bottom surface does not reach the surface of the substrate.

11. The semiconductor device according to claim 1, wherein a peak concentration of an impurity of the first conductivity type in the first well is higher than 10¹⁶ cm⁻³ but lower than 10¹⁸ cm⁻³ at a depth between 1.5 μm and 2.5 μm below the surface of the substrate.

12. The semiconductor device according to claim 11, wherein
the second portion of the second well is formed at a depth between 2 μm and 4 μm below the surface of the substrate, and
a peak concentration of an impurity of the second conductivity type in the second well is higher than the peak concentration of the impurity of the first conductivity type in the first well.

13. The semiconductor device according to claim 1, wherein a voltage in a range of −1 V to −4 V with respect to a potential of the substrate is applied to the first well.

14. The semiconductor device according to claim 1, further comprising:
a second transistor adjacent to the first transistor; and
an electrode diffusion layer that forms a main electrode of each of the first and second transistors.

15. The semiconductor device according to claim 1, further comprising:
a second transistor that includes a gate insulating film thinner than the first insulating film.

16. The semiconductor device according to claim 1, wherein the first transistor includes a main electrode electrically connected to a gate electrode of one of the memory cell transistors.

17. A semiconductor device, comprising:
a memory cell array including a plurality of memory cell transistors; and
a peripheral circuit including:
a semiconductor substrate,
a first well of a first conductivity type in the semiconductor substrate,
a second well of a second conductivity type that electrically separates the first well from the semiconductor substrate and includes:
a first portion surrounding a side surface of the first well, and
a second portion contacting a bottom portion of the first well and having a side surface contacting a side surface of the first portion,
a third well of the first conductivity type in the semiconductor substrate, the third well surrounding the first portion of the second well but spaced separated therefrom, and
an insulated gate type field effect transistor that includes a gate electrode facing the first well via an insulating film, wherein
a bottom surface of the first portion of the second well is closer to a surface of the substrate than a bottom surface of the second portion of the second well.

18. The semiconductor device according to claim 17, further comprising:
a plurality of first and second wirings, wherein
the memory cell transistors are formed at intersections of the first and second wirings, and
the field effect transistor includes a main electrode electrically connected to one of the first wirings and through which a voltage is applied to the wiring.

19. A method for manufacturing a semiconductor device, the method comprising:
forming, in a semiconductor substrate of a first conductivity type, a side surface region of a first portion that is of a second conductivity type;
forming, by an ion implantation process:
a connection region of the first portion along and inside the side surface region in the semiconductor substrate, and
a second portion of the second conductivity type inside the connection region in the semiconductor substrate such that a bottom surface of the connection region is closer to a surface of the semiconductor substrate than a bottom surface of the second portion;
forming, in the substrate, a first well of the first conductivity type facing the second portion inside the side surface region and the connection region;
forming, in the substrate, a third well of the first conductivity type surrounding the side surface region to be separated therefrom, a bottom surface of the third well is closer to the surface of the semiconductor substrate than a bottom surface of the side surface region; and
forming a transistor in which a main electrode is disposed in the first well and which has a gate electrode facing the first well via a gate insulating film disposed on an upper surface of the first well, wherein
the first well and the semiconductor substrate are electrically separated by the first and second portions.

20. The method according to claim 19, wherein the connection region is formed so that a boundary between the connection region and the semiconductor substrate approaches the surface of the semiconductor substrate as a distance from the first well increases.
